(19) United States
(12) Patent Application Publication
(10) Pub. No.: US 2015/0108604 A1
(43) Pub. Date: Apr. 23, 2015

(54) SEMICONDUCTOR MODULE CARRYING THE SAME

(71) Applicant: Hirofumi Nakamura, Yokohama-shi (JP)

(72) Inventor: Hirofumi Nakamura, Yokohama-shi (JP)

(73) Assignee: ZyCube Co., Ltd., Yokohamam-shi, Kanagawa (JP)

(21) Appl. No.: 14/369,042

(22) PCT Filed: Dec. 26, 2011
(86) PCT No.: PCT/JP2011/080134

§ 371 Date: Nov. 26, 2014

(51) Int. Cl. H01L 23/00; H01L 49/02

(52) U.S. Cl. CPC H01L 24/17; H01L 28/60; H01L 24/49; H01L 2924/14; H01L 2924/1205
USPC 257/532; 257/737

(57) ABSTRACT

In the conventional high-speed, large-current semiconductor chip, all the electric connecting terminals were placed on one surface of the chip. For this reason, to supply stable supply currents or reduce noises mixed into the signal system from the power supply, many terminals were assigned to supply current inflow terminals and supply current outflow terminals. As a result, there is a problem that the terminal number of a semiconductor device is increased and the mounting area thereof is increased.

The electrical connecting terminals for power supply system and those for signal system are separately placed on both sides of a semiconductor chip. By the configuration to enlarging the permissible current value of a path through which a large current flows, stabilization of feeding supply currents, reduction of noises mixed into signal systems, reduction of mounting areas due to pin count reduction, and increase of heat dissipation effects can be realized even with a decreased pin count. Moreover, by the semiconductor module on which the semiconductor chip is mounted, stable characteristics can be realized even in high-speed operation necessitating large currents.

### TECHNICAL FIELD

The present invention relates to a construction method of a high pin-count or high-power semiconductor device. The present invention is also relates to a construction method of a semiconductor module carrying this semiconductor device.

### BACKGROUND ART

In recent years, technological advances in semiconductor devices are large, and semiconductor devices have been widely used in industrial and consumer equipment. As a result, technological advances has contributed significantly to size reduction, weight reduction, price lowering, and performance advancement of equipment and systems carrying semiconductor devices. On the other hand, the request to improving semiconductor devices is not stopped and as a result, higher integration, higher speed, and more sophistication as well as miniaturization are expected. If these requirements are met, the pin count and electric power of semiconductor devices will be necessarily increased. In addition, if the high power and high operation speed of semiconductor devices advances, appropriate design of power supply paths or the like will be essential. For example, if the power supply paths are unstable, the circuit operation becomes unstable, and noise is likely to be superposed on the input/output signals, causing malfunction. With such the design of power supply paths, a method of assigning power supply terminals and/or ground terminals to a lot of pins in parallel to thereby stabilize the power supply paths has been frequently used. This design approach is effective; however, on the other hand, this approach promotes the multiple pin structure furthermore. As a result, it is pointed out that the count of connection points between an external circuit and a semiconductor device is increased, lowering the connection reliability. Furthermore, it is also pointed out that there is a disadvantage that the footprint is inevitably enlarged when mounting a semiconductor device on an application system.

With a multi-pin, high-power, high-speed semiconductor device, the following items are important:

(1) Allocation of “terminals” of a semiconductor device as a power supply path and the way of their placement
(2) Preventing noises from entering the input/output signals to cause a malfunction
(3) Reducing the count of pins to ensure the connection reliability and to reduce the footprint
(4) Heat dissipation structure for reducing the chip temperature increase

Among these items, the item (1) is particularly important.

An examples of the state of the art is shown below.

(a) FIG. 14 shows the pin layout tables of an Intel CPU (Pentium 4) (Pentium is a registered trademark), which correspond to FIG. 9 (on Page 39) and FIGS. 10 and 11 (on Pages 42 to 43) of the Non-Patent Document 1 cited below. In the total pin count of 775, 415 pins (which are equivalent to about 55% of the total pin count) are allocated to current inflow terminals (VCC) and current outflow terminals (VSS) (where the current outflow terminals are ground terminals to which the power supply current is returned). In this figure, the terminals VCC are drawn in solid gray and the terminals VSS are drawn by oblique lines.

(b) With the CPU designed for HPC (supercomputer), about 6000 pins out of 8000 pins in total are assigned to power supply and ground. Since the current value flowing from the power source reaches 100 amperes (instantaneous value) in the CPU, a single terminal is insufficient in capacity. For this reason, a plurality of terminals are used in parallel to enlarge the capacity; however, more than that, more terminals are inevitably assigned to the power supply system (current inflow terminals and current outflow terminals) for “stable power supplying” at the present state.

FIG. 15 are figures showing the structure of a Pentium 4 listed on FIG. 4 (Page 33) of the Non-Patent Document 1 cited below. FIG. 15(a) shows the part of the semiconductor device, and FIG. 15(b) shows the socket portion thereof. As shown in FIG. 15(a), this semiconductor device comprises a semiconductor chip (which is labeled Core), a substrate mounted with capacitors (which is labeled Substrate), a cap for dissipating the heat generated in the semiconductor chip (which is labeled IHS, Integrated Heat Spreader), and a thermally conductive material for raising the thermal conductivity which is inserted into between the semiconductor chip and the cap (which is labeled TIM, Thermal Interface Material). The semiconductor chip is flip-chip connected to the substrate in such a way that the circuit surface is faced to the lower side. In this configuration, all the electrical connections to the semiconductor chip are made on the circuit surface (the lower surface in the figures). In other words, the inflow of the power supply current, the outflow of the power supply current, the inflow of the input/output signals, the outflow of the input/output signals are done on one side of the semiconductor chip. With this structure, all the currents (the power supply current and the input/output signals) flow in and flow out through a single plane; therefore, the pattern design and layout of the power supply paths and the signal transmission paths are complicated. As a result, it is a current situation that many pins are inevitably assigned and arranged for power supplying. In addition, even in the most advanced CPU (Intel Core i7) also, a similar device structure is used.

Furthermore, with the configuration of FIG. 15, the heat (which occurs on the surface where the electronic circuits are arranged) generated in the semiconductor chip is dissipated from the cap surface by way of the thermal interface material by flowing the thermal energy along the thickness direction of the semiconductor chip. Since the thermal conductivity of the semiconductor chip is lower than that of metal (about 40% of copper), it is said that the cooling effect of the semiconductor chip using the aforementioned heat radiating path is not sufficient.

Moreover, since a large current flows through the power supply path, if the electromagnetic field generated by this current is applied to the input/output signal paths, a noise is superposed onto the signals flowing through the input/output signal paths. Such the noise may cause malfunction of the semiconductor device; in particular, such the noise will induce a serious problem in the case of faster operation. In order to prevent the superposition of such the noise, in the configuration of FIG. 15, the group of the power supply system terminals and the group of the input/output system terminals are separately arranged in such a way that electromagnetic interference is less likely to occur. To realize such the arrangement, the pattern design for the semiconductor chip and the substrate is made complicated.

If “stable power supplying” is made possible with a small number of pins, the pin count of the semiconductor device can be reduced, and the footprint of the substrate can also be reduced. In addition, when the semiconductor device is incorporated into an application system or the like, the number of electrical connection points is decreased, thereby improving the connection reliability and making high-density mounting possible. For this reason, with the multi-pin, high-power, high-speed semiconductor device, it is strongly desired to develop a semiconductor device configuration that achieves “stable power supplying”, prevents the noise from being superposed onto the input/output signals, and reduces the count of pins for connection (the count of terminals), and mounting techniques related therewith.

In general, a semiconductor device comprises a semiconductor chip and a package. Therefore, in order to cope with the current situation in the conventional semiconductor device as described in the previous paragraphs, both of the semiconductor chip and the package need to be considered. That is, in order to break through the aforementioned current situation of the conventional semiconductor device, improvement of the semiconductor chip embedded in the semiconductor device will be first. Further, if improvement of the semiconductor chip is realized, a semiconductor device carrying the semiconductor chip and a semiconductor module carrying the semiconductor chips will be also improved.

### PRIOR ART DOCUMENTS

### Non-Patent Documents

[Non-Patent Document 1] Data Sheet, Document Number: 310308-002, “Intel Pentium 4 Processor 6X1 Sequence” Intel Corporation, January 2007 edition

### DISCLOSURE OF THE INVENTION

### Problems to be Resolved by the Invention

With a multi-pin, high-power, high-speed semiconductor device, such as a CPU (IC for arithmetic processing) and a GPU [IC for image processing], which is now used widely, a lot of pins (terminals) are assigned to the power supply system in order to realize “stable power supplying”. For this reason, one problem is to develop a semiconductor device capable of “stable power supplying” even with a small number of terminals due to a terminal configuration or the like where allowable current values are large.

In high-speed operation, mixing of noise into the input/output signals from the wiring lines through which large currents flow cause a malfunction. Therefore, another problem is to reduce the mixing of the noise as small as possible.

There is a tendency that the count of pins increases as the degree of integration of semiconductor devices is raised. Moreover, as described above, the count of pins assigned to the power supply system becomes large with the increasing power. Therefore, a still another problem is to reduce the pin count, thereby ensuring the connection reliability and reducing the mounting area for mounting the semiconductor device on an application system.

In particular, a heat dissipation mechanism is important for high-power semiconductor devices. As described above, the thermal conductivity of silicon semiconductor is smaller compared with that of metal and therefore, a further problem is to achieve a more efficient heat-radiating configuration.

### Means for Solving the Problems

In the present invention, (1) a first terminal group comprising a terminal through which an input signal flows into a semiconductor chip and a terminal through which an output signal flows out from the semiconductor chip, and (2) a second terminal group comprising a terminal through which an input signal flows out from the semiconductor chip and a terminal through which an output signal flows into the semiconductor chip are placed on a first main surface of the semiconductor chip on which electronic circuits are integrated; and (3) a third terminal group comprising a terminal through which a power supply current flows into the semiconductor chip, and (4) a fourth terminal group comprising a terminal through which a power supply current flows from the semiconductor chip are placed on a second main surface of the semiconductor chip; wherein the second main surface is opposite to the first main surface.

In this specification, related terms are classified as follows:

### Semiconductor Chip:

This means a chip cut out by scribing from a wafer formed through a diffusion process. At least one semiconductor element (which is a generic term of transistors, diodes or the like) constituting an electronic circuit, more commonly, a plurality of semiconductor elements, are arranged on the chip. On a first main surface of the chip on which the electronic circuits are arranged, “terminals” for electrically connecting the chip to an external circuit are arranged. If this electrical connection is realized by the wire bonding connection, the “terminals” are formed by metal (which is often aluminum), which are exposed from openings of an oxide film. If this electrical connection is realized by the ball grid connection that copes with the surface mounting method, conductive balls (which is often made of solder) are provided for the “terminals”. Further, in general, the second main surface and side faces of the semiconductor chip are in the state of “bare” and no protective layer is disposed on the second main surface and the side faces thereof. The “chip size package (CSP)” is the same (or, nearly the same) in size as a semiconductor chip, as its name implies, and seems to be equivalent to a “semiconductor chip” in outward appearance. However, the chip is “packaged” to ensure environmental resistance and therefore, the “chip size package (CSP)” is not termed a “semiconductor chip” in this specification.

### Semiconductor Device:

This means a structure that the semiconductor chip is enclosed in a package. Since a semiconductor device is packaged, environmental resistance is excellent. There are a lot of types of the package. A semiconductor device may be classified in diverse methods, one of which is described below.

(1) Classification by packaging material: To cover the semiconductor chip with a hard material of a ceramic or plastic system is the mainstream. There is also the TCP (or TAB) which is equipped with a semiconductor chip mounted on a tape-shaped plastic film. Recently, to direct the miniaturization of semiconductor devices, so-called chip size packages are in practical use, where a plate (interposer) made of a resin or the like is placed on the back of a semiconductor chip, and terminals are arranged on the back side of this plate.

(2) Classification by implementation method: There are the through-hole mounting type that bar-shaped terminals for electrical connection are inserted into holes of a printed wiring board and fixed with solder, and the surface-mounting type where plate- or ball-shaped terminals are fixed on a conductive foil formed on the surface of a printed wiring board with solder.

(3) Classification by shape and direction of terminals: There are the shape of a package on which bar- or plate-shaped leads are arranged along one or two directions of a package (typically, DIP), the shape of a package on which plate-shaped leads are arranged along four directions of a package (typically, QFP), and the shape of a package on which ball-shaped terminals are arranged in a matrix array on the back of a package (typically, BGA).

### Semiconductor Module:

This means a structure that the one or more semiconductor chips are combined with electronic parts (including discrete components such as resistors and capacitors) or the like, thereby constituting a “part”. The structural elements and scale and appearance of the module are wide-ranging. In general, the aforementioned semiconductor device and the semiconductor chip are produced by semiconductor manufacturers; on the other hand, the semiconductor module is produced by not only semiconductor manufacturers but also parts manufactures or equipment manufacturers. It is usual that the semiconductor module has a system-specific structure to an application system to be installed, and that a specific function is realized using general-purpose semiconductor devices and electronic components.

### Electronic Part:

This means a part which is also referred as a passive element and includes a resistor, capacitor, inductor (coils) and so on. There is a structure (e.g., module resistor) formed by combining a plurality of single elements (discrete parts) together.

In this specification, the terminals of the semiconductor chip are classified as follows:

### Supply Current Inflow Terminal:

This is a terminal which is connected to a DC power supply driving the semiconductor chip, and into which a large current inflows. This is denoted VDD, VCC and the like in many cases.

### Supply Current Outflow Terminal:

This is a terminal from which a current flowing into a “supply current inflow terminal” outflows, and which is connected to a DC power supply. This is denoted VSS, GND and the like in many cases.

### Input Signal Inflow Terminal:

This is a terminal into which a signal such as a clock, data, or control signal inflows.

### Input Signal Outflow Terminal:

This is a terminal from which a signal current flowing into an “input signal inflow terminal” outflows.

### Output Signal Outflow Terminal:

This is a terminal from which a signal such as a bus or status signal outflows.

### Output Signal Inflow Terminal:

This is a terminal into which a signal current flowing from an “output signal outflow terminal” inflows as a return current.

The “input signal outflow terminal” and the “output signal inflow terminal” described above are denoted GND (which is denoted “GND2” in this paragraph) in many cases. Moreover, since currents flowing through these “input signal outflow terminal” and the “output signal inflow terminal” are small, they may be communized to reduce the terminal count. The “supply current outflow terminal” also may be denoted GND (which is denoted “GND1” in this paragraph); however, the current values of GND2 and GND1 are largely different from each other. For this reason, in the case where the semiconductor chip is enclosed in a package to form a semiconductor device or in the case where connection to an external circuit is performed by way of this package, it is necessary that GND 2 and GND1 are formed by different wiring to separate a signal system from a power supply system, thereby avoiding interference. As the terminals for input/output signals, a circuit configuration termed “tri-state” may be adopted. The “tri-state” is a method of switching among (1) the function as signal input terminals, (2) the function as signal output terminals, and (3) the function of insulating from a circuit system to be connected by setting the output impedance as a high impedance by control means. In such the “tri-state”, the terminals for input/output signals may be the “input signal inflow terminals” or the “output signal outflow terminals” dependent on time. In this specification, a terminal designed for the “tri-state” is considered equivalent to the aforementioned “input signal inflow terminal” for the sake of convenience. In addition, a partner terminal (which is equivalent to GND2) with which a pair is formed by the “tri-state” terminal is considered equivalent to the aforementioned “input signal outflow terminal” for the sake of convenience.

In the configuration described in the above paragraphs, output signals and input signals are connected to one surface (the aforementioned first main surface on which electronic circuits are formed) of the semiconductor chip, and wiring for power supply is formed on the opposite surface (the aforementioned second main surface) of the semiconductor chip. Specifically, with a conventional semiconductor chip, all the terminals for the input signals, output signals, and power supply are connected to the aforementioned first main surface. On the other hand, in the present invention, two sides of the semiconductor chip are used for different purposes; an input/output signal system (which includes GND2 to which currents are returned) through which small currents flow is placed on one side (e.g., the aforementioned first main surface) and a power supply system (which includes GND1 to which currents are returned) through which large currents flow is placed on the other side (e.g., the aforementioned second main surface). This is the feature of the present invention.

In order to use the two sides of the semiconductor chip for different purposes, wiring that penetrates the thickness direction of the semiconductor chip (which is called TSV [through silicon via] or through electrode) is essential for electrically connecting the electronic circuits disposed on the first main surface to the third terminal group or the fourth terminal group disposed on the second main surface.

Since a large current flow through the “penetration wiring” as described in the preceding paragraph, the “penetration wiring” needs to have a configuration such that an allowable current value is large. For example, the cross-sectional area of the “penetration wiring” may be increased, a plurality of the “penetration wirings” may be provided to be connected in parallel, or a low-resistivity material may be used for the “penetration wiring”. In particular, when the “penetration wiring” is composed of a material with a low resistivity such as copper, the thermal conductivity is also increased; therefore, there is an advantageous effect that the heat generated by the electronic circuits disposed on the first main surface side of the semiconductor chip is efficiently dissipated toward the second main surface side thereof. Further, this effect of the heat dissipation is increased furthermore by increasing the areas of the terminals forming the third terminal group or the fourth terminal group disposed on the second main surface.

(1) At least one of the terminals constituting the third terminal group is/are connected to a first conductive layer disposed on the second main surface side of the terminal, (2) at least one of the terminals constituting the fourth terminal group is/are connected to a second conductive layer disposed on the second main surface side of the terminal, and (3) a capacitor is constituted using the first conductive layer and the second conductive layer.

Between the “supply current inflow terminal” and the “supply current outflow terminal”, a capacitor with a large capacitance that absorbs the fluctuation of the supply voltage and a capacitor with a small capacitance that absorbs the noises such as a switching noise induced by the supply current changing at high speed are often connected in parallel. In such the connection, since the volumes of the capacitors are large, in particular, the large-capacitance capacitor is often disposed at the outside (for example, on a printed circuit board on which the semiconductor device is mounted) of the semiconductor device on which the semiconductor chip is mounted. On the other hand, it is preferred that the “small-capacitance capacitor” is disposed near the semiconductor chip as much as possible from the viewpoint of noise reduction. In the configuration described in the preceding paragraph, at least two conductive layers are formed on the second main surface side, and two of these conductive layers are used as a pair of opposite electrodes, thereby constituting the aforementioned small-capacitance capacitor.

The “at least two conductive layers” as described in the preceding paragraph is formed by a process of, on the second main surface, (1) forming an insulating layer, (2) forming a first conductive layer made of a patterned metal or the like, (2) forming an insulating layer on the first main surface, and (3) forming a second conductive layer made of a patterned metal or the like. By repeating this process, three of more conductive layers can be formed. To constitute the capacitor by the first conductive layer” and the “second conductive layer”, these two conductive layers need to be “overlapped spatially”. Additionally, “the first conductive layer” is connected to a specified terminal that constitutes a group of the “supply current inflow terminals”, and “the second conductive layer” is connected to a specified terminal that constitutes a group of the “supply current outflow terminals”. By this configuration, the small-capacitance capacitor is electrically disposed between the group of the “supply current inflow terminals”, and the group of the “supply current outflow terminals”.

In the preceding paragraph, it is described that the small-capacitance capacitor is constituted by the “first conductive layer”, and the “second conductive layer”. However, the configuration of the small-capacitance capacitor is not limited to this. For example, the count of the conductive layers mentioned above is set at three or more and then, the odd-numbered conductive layers are communized to form the “first conductive layer” and the even-numbered conductive layers are communized to form the “second conductive layer”. With this configuration, the capacitance of the small-capacitance capacitor can be increased easily.

The number of the small-capacitance capacitor is not limited to one. As an example, a plurality of the small-capacitance capacitors are disposed on the second main surface of the semiconductor chip, a set of designated terminals is formed by selection from a plurality of the “supply current inflow terminals” and a plurality of the “supply current outflow terminals”, and these small-capacitance capacitors are disposed for the respective terminal sets.

An electric wiring layer made of at least one layer is formed on the first main surface of the semiconductor chip, and the first terminal group and the second terminal group are electrically connected to this electric wiring layer.

With the highly integrated semiconductor chip, a lot of terminals to which input/output signals are connected are arranged on a designated area of the first main surface of the chip (e.g., a peripheral region of the chip). In the case where the semiconductor chip is applied to an application system, it may be required that the connection state of the terminals are changed by “rewiring” in accordance with the peculiar specification of the application system. For example, address fixed for reducing the terminal number for connection (which is to remove the address terminals which can be controlled from the outside), chip select fixed (which is to set a state that the chip is selected at all times), or the like are required. As another example, a semiconductor chip fabricated on the precondition that wire bonding connection is used (where the terminal group is arranged at the four sizes of the chip periphery) is converted to a chip for ball grid connection where surface mounting is possible (a new terminal group is arranged on the entire surface of the chip two-dimensionally). Such the “rewiring” is carried out on the user side in many cases after obtaining the semiconductor chip which has been completed (or, which is in the state of a wafer). In the configuration described in the preceding paragraph, a conductive layer comprising at least one layer is disposed on the first main surface of the semiconductor chip, and the “input signal inflow terminals”, the “output signal outflow terminals” (both of which correspond to the first terminal group), the “input signal outflow terminals”, and/or the “output signal inflow terminals” (both of which correspond to the second terminal group) are subjected to rewiring. By such the rewiring, it is possible to realize a configuration that satisfies the peculiar specification (electric and mechanical) of the application system.

It is possible to further develop the configuration as described in the preceding paragraph and to mount another semiconductor chip or semiconductor device or electronic part on the surface of the electric wiring layer. In this configuration, the electrical wiring layer will form electrical connection means between the semiconductor chip and the aforementioned “semiconductor chip or semiconductor device or electronic part”.

A semiconductor module including an interposer and the semiconductor chip as structural elements is configured by (1) mounting at least one semiconductor chip including the semiconductor chip on the interposer, (2) disposing the first main surface of the semiconductor chip on the interposer in such a way that the first main surface of the semiconductor chip is directed to the side of the interposer, (3) electrically connecting the first terminal group and the second terminal group to the interposer by a connecting method including the ball grid array, and (4) electrically connecting the third terminal group and the fourth terminal group to the interposer by a connecting method including the wire bonding,

The material constituting the interposer is a semiconductor such as silicon, resin, or the like. In the configuration described in the preceding paragraph, the semiconductor chip is mounted on the interposer, the input/output system signals are connected to the interposer from the lower side (which is the first main surface) of the semiconductor chip by connecting means such as ball grids, and the power supply system wiring are connected to the upper side (which is the second main surface) of the semiconductor chip by connecting means such as bonding wires. In the case of using bonding wires, one end of each bonding wire is connected to the surface side of the interposer (the side where the semiconductor chip is mounted) from the viewpoint of fabrication technology. Since a large current for power supplying flows through the bonding wire, it is preferred that a thick wire (100 micrometers or more, for example) is used. Alternatively, two or more bonding wires may be arranged in parallel. Furthermore, if increasing the mounting density is directed, it is preferred that the semiconductor module comprises connection means such as ball grid array (BGA) and that this semiconductor module is surface-mounted on a printed circuit board or the like. However, the present invention is not limited to this. In the configuration described above, the large current for power supplying flows through (1) the printed circuit board, (2) the ball grid of the semiconductor module (which is disposed on the lower side of the interposer), (3) the through wiring formed on the interposer, (4) the aforementioned thick bonding wire (or the plurality of bonding wires), (5) the terminal constituting the third terminal group (the fourth terminal group for the return current) of the semiconductor chip, (6) the through wiring interconnecting the second and first main surfaces of the semiconductor chip, and (7) the electronic circuits formed on the semiconductor chip in this order. It is necessary for these current paths that the permissible current value is large and the impedance is low in order not to cause voltage drop and voltage fluctuation even if a large current flows through these current paths.

The large current for power supplying as described in the preceding paragraph passes through the through wiring of (3). Therefore, it is necessary to increase the permissible current value of the through wiring by increasing the cross-sectional area thereof or using a plurality of through wirings in parallel. Moreover, it is effective to use a low resistivity material such as copper for the material of the through wiring. Furthermore, when copper or the like is used, it has a large thermal conductivity and therefore, the heat generated in the electronic circuits disposed on the first main surface side of the semiconductor chip can be transmitted along the thickness direction of the interposer and then, dissipated to the side of the printed circuit board by way of the ball grid disposed on the lower side surface of the interposer. This means that the heat dissipation of the semiconductor module can be effectively performed.

In the configuration described above, the input/output signal system current flows through (1) the printed circuit board, (2) the ball grid of the semiconductor module (which is disposed on the lower side surface of the interposer) (3) the through wiring formed in the interposer, (4) the terminal constituting the first terminal group (or, the second terminal group) of the semiconductor chip, and (5) the electronic circuits formed in the semiconductor chip in this order. Since the input/output signal system current is small, it is unnecessary to enlarge the permissible current value in particular. For example, the diameter of the through wiring of (3) may be 10 micrometer or less. An example to be considered in design is not to increase the permissible current value but to arrange the first terminal group or the second terminal group in a higher density.

The number of the semiconductor chip mounted on the semiconductor module is not necessarily one. For example, a semiconductor chip for an arithmetic processing system and one or more semiconductor chips for a storage system may be mounted on the interposer, and a semiconductor chip for an arithmetic processing system, a semiconductor chips for an analog-to-digital conversion system, and a semiconductor chip for a sensor system may be mounted on the interposer. Thus, he semiconductor chips may be mounted in various forms.

(1) On the second main surface side of the first semiconductor chip, the first main surface side of which is opposed to the interposer side, a second semiconductor chip or a second semiconductor device or a second electronic part is mounted, and (2) the second semiconductor chip or the second semiconductor device or the second electronic part is electrically connected to the first semiconductor chip.

Conventionally, 5V has been adopted as a standard supply voltage of the logic circuitry. However, to cope with higher integration and higher speed, lower supply voltages have been promoted to reduce power consumption and heat generation. For example, the supply voltage reduction to 1.5 V has been progressed from that to 3.3 V for CPUs, and further reduction (reduction to 1.3 V, for example) is in progress for the mobile devices. However, if the supply voltage is reduced, the signal amplitude becomes smaller and the resistance to noise contamination from the outside becomes lower. For this reason, the demand to 5 V is still strong for device-to-device connections. Even in the aforementioned semiconductor module, it is often that, for example, a supply voltage of 1.5 V is used for the high-speed processing system circuitry and at the same time, a supply voltage of 3.3 V or 5 V is used for the interface system circuitry or the peripheral system circuitry. Therefore, from the viewpoint of reducing the number of connection terminals, it is preferred that one kind of power supply (3.3 V, for example) is used for the semiconductor module, and that this power supply voltage is converted into other voltage (1.5V, for example) in the inside of the semiconductor module. The previous paragraph is described for such the situation, where the second semiconductor chip or the second semiconductor device chip includes a power supply circuit converting 3.3 V to 1.5 V or the like. However, the second semiconductor chip, the second semiconductor device, or the second electronic part does not always include the aforementioned power supply circuit.

In the configuration described in the paragraph two times before, a further semiconductor chip, a further semiconductor device, a discrete component such as a transistor, or an electronic part such as a capacitor may be disposed on the second main surface of the semiconductor chip, in addition to the second semiconductor chip or the second semiconductor device. In particular, in the form of mounting a power supply system semiconductor chip or the like, it is preferred to mount a capacitor for voltage stabilization.

A semiconductor module comprising an interposer and the semiconductor chip as structural elements is configured by (1) mounting at least one semiconductor chip including the aforementioned semiconductor chip on the interposer, (2) placing the semiconductor chip on the interposer in such a way that the second main surface side of the semiconductor chip is opposed to the interposer side, (3) electrically connecting the third terminal group and the fourth terminal group to the interposer by a connecting method including a ball grid array, and (4) electrically connecting the first terminal group and the second terminal group to the interposer by a connecting method including a wire bonding.

If a power supply current flowing into the semiconductor module is large, it is preferred to prevent unnecessary electromagnetic radiation and the drop of the supply voltage by making the supply path of the power supply current as short as possible. In the configuration described in the preceding paragraph, the third terminal group or the fourth terminal of the semiconductor chip is disposed so as to be opposed to the interposer, and the supply current is supplied via a ball grid or the like. In such the configuration, a bonding wire is not used and thus, shorter wiring is possible. Further, the input/output signal system (the first terminal group and the second terminal group) is electrically connected to the interposer by connecting means such as wire bonding. For this reason, although the number of bonding wires is increased, this does not cause a major issue from the viewpoint of fabrication technology if an automatic bonding machine or the like is used.

A semiconductor module comprising an interposer and the semiconductor chip as structural elements is configured by (1) a fourth semiconductor chip or a fourth semiconductor device or a fourth electronic part is mounted on the first main surface side of the third semiconductor chip, the second main surface side of which is opposed to the interposer side, and (2) electrically connecting the fourth semiconductor chip or the fourth semiconductor device or the fourth electronic part to the third semiconductor chip.

When electrically connecting the fourth semiconductor chip or the fourth semiconductor device or the fourth electronic part to the third semiconductor chip, it is preferred that the aforementioned “rewiring layer” is disposed on the first main surface of the third semiconductor chip, thereby ensuring the easiness of this electrical connection. In particular, when the semiconductor chip is designed as a general-purpose product, the arrangement of the electrical connection terminals of the third semiconductor chip does not always correspond to the arrangement of the electrical connection terminals of the fourth semiconductor chip or the fourth semiconductor device. For example, the arrangement pitches of these electrical connection terminals are different in many cases. Therefore, by designing appropriately the rewiring layer, it is possible to “absorb” the difference between the arrangement pitches with the rewiring layer, thereby ensuring the easiness of connection. Such the rewiring layer can be formed by a well-known manner and is generally composed of two or more electric wiring layers.

In the configuration described in the paragraph two times before, it is shown that the single “third semiconductor chip or the semiconductor device or the electronic part” is mounted on the first main surface of the third semiconductor chip. However, two or more semiconductor chips or semiconductor devices or electronic parts may be mounted. For example, a line driver, a multiplexer, an interface (e.g., a wireless transmission/reception circuit), an analog-to-digital converter, an operational amplifier, a sensor such as a temperature sensor, and a power supply circuit (e.g., a voltage step-up circuit, the capacity is not always large) may be used independently or in combination. In addition, a capacitor for power supply voltage stabilization or noise absorption, an inductor in a step-up circuit or a radio circuit, and a thermistor for temperature detection may be mounted.

A semiconductor module comprising an interposer and the semiconductor chip as structural elements is configured by (1) placing the third semiconductor chip on the interposer in such a way that the second main surface side of the third semiconductor chip is opposed to the interposer side, (2) placing a second interposer on the first main surface side of the third semiconductor chip, (3) electrically connecting the second interposer to the third semiconductor chip, (4) placing a fifth semiconductor chip or a fifth semiconductor device or a fifth electronic part on the second interposer, (5) electrically connecting the fifth semiconductor chip or the fifth semiconductor device or the fifth electronic part to the second interposer, and (6) electrically connecting the second interposer to the interposer by a connecting method including a wire bonding.

The semiconductor module having the configuration described in the preceding paragraph comprises the interposer, the (third) semiconductor chip, the second interposer, the fifth semiconductor chip (or the semiconductor device or the electronic part). (In the order from the lower side.) The second interposer is placed to ensure the easiness of electrical connection between the semiconductor chip and the fifth semiconductor chip or the fifth semiconductor device or the fifth electronic part. Such the situation is to realize the same function as the “rewiring layer” described above. If it is difficult to form the rewiring layer on the first main surface of the semiconductor chip mentioned above, (for example, the number of the electrical wiring layers of the rewiring layer is not enough for complete rewiring), it is effective to dispose the second interposer as an alternative of the rewiring layer. The second interposer may be an interposer which is formed by processing a resin substrate or a semiconductor interposer which is obtained by processing a silicon substrate. These interposers can be formed by a well-known method.

In the configuration described in the paragraph two times before, the single “second interposer” and the single “fifth semiconductor chip or semiconductor device or electronic part” are disposed with respect to the semiconductor chip; however, the present invention is not limited to this. For example, (1) a configuration comprising the over two “fifth semiconductor chips or semiconductor devices or electronic parts” are disposed on the single “second interposer” with respect to the semiconductor chip, (2) a configuration comprising the over two “second interposers” are disposed on the semiconductor chip, and the single “fifth semiconductor chip or semiconductor device or electronic part” is disposed on the surface of each of these “second interposers”, and (3) a configuration comprising the over two “second interposers” are disposed on the semiconductor chip, and the over two “fifth semiconductor chips or semiconductor devices or electronic parts” are disposed on the surface of each of these “second interposers” may be used.

### Advantageous Effects of the Invention

According to the present invention, (1) a semiconductor chip or semiconductor device capable of “stable power supplying” can be realized even if the number of the terminals is small due to a terminal configuration with a large permissible current value and so on, (2) the noises which are mixed into the input/output signal system wiring from the power supply system wiring, which has been an issue during high-speed operation, can be reduced, (3) the connection reliability can be ensured due to reduction of the number of the terminals, (4) the area for implementing the semiconductor device(s) or the semiconductor chip(s) can be reduced, and (5) the heat generated in the semiconductor chip can be dissipated effectively.

By dividing the terminals disposed on the semiconductor chip and disposed them on the first main surface and the second main surface of the semiconductor chip in accordance with the purposes of use, the advantageous effects as described in the preceding paragraph are obtained. The arrangement of the terminals are illustrated specifically as follows:

The first main surface: the terminal group into which the input signal inflows, the terminal group from which the output signal outflows, the terminal group from which the input signal outflows, and the terminal group into which output signal inflows

The second main surface: a terminal group into which a power supply current inflows, and a terminal group from which a power supply current outflows

In the previous paragraph, a capacitor may be disposed between the terminal group into which a supply current inflows and the terminal group from which a supply current outflows, thereby making it possible to absorb transient noises (switching noises) having a high frequency component.

By disposing an electrical wiring layer on the first main surface of the semiconductor chip and electrically connecting the terminal group of the semiconductor chip, rewiring can be performed.

A semiconductor module can be realized by electrically connecting the terminal group for the input/output system which is disposed on the first main surface side of the semiconductor chip to the interposer by way of a ball grid array, and electrically connecting the terminal group for the power supply system which is disposed on the second main surface side of the semiconductor chip to the interposer by way of thick bonding wires.

A semiconductor module can be realized by electrically connecting the terminal group for the input/output system which is disposed on the first main surface side of the semiconductor chip to the interposer by way of a ball grid array, and electrically connecting the terminal group for the power supply system which is disposed on the second main surface side of the semiconductor chip to the interposer by way of thick bonding wires, and further disposing the second semiconductor chip (e.g., a semiconductor chip for converting the power supply voltage) on the second main surface side.

A semiconductor module can be realized by electrically connecting the terminal group for the power supply system which is disposed on the second main surface side of the semiconductor chip to the interposer by way of a ball grid array, and electrically connecting the terminal group for the input/output system which is disposed on the first main surface side of the semiconductor chip to the interposer by way of bonding wires.

A semiconductor module can be realized by electrically connecting the terminal group for the power supply system which is disposed on the second main surface side of the semiconductor chip to the interposer by way of a ball grid array, and electrically connecting the terminal group for the input/output system which is disposed on the first main surface side of the semiconductor chip to the interposer by way of bonding wires, and further disposing the third semiconductor chip (e.g., a peripheral IC) on an electrical wiring layer which is placed on the first main surface side.

A semiconductor module can be realized by electrically connecting the terminal group for the power supply system which is disposed on the second main surface side of the semiconductor chip to the interposer by way of a ball grid array, and disposing the fourth semiconductor chip (e.g., a peripheral IC) on the second interposer which is disposed on the first main surface side of the semiconductor chip, and further electrically connecting the terminal group for the input/output system which is disposed on the first main surface side of the semiconductor chip and the second interposer to the interposer by way of bonding wires.

### BRIEF DESCRIPTION OF THE DRAWINGS

FIG. 1 is a diagram showing the internal connections of a semiconductor device.

FIG. 2 is a diagram showing the structure of a semiconductor chip according to a first embodiment of the present invention.

FIG. 3 is a diagram showing the structure of a semiconductor chip according to a second embodiment of the present invention.

FIG. 4 is a diagram showing the structure of a semiconductor device (with a chip-size package form) according to a third embodiment of the present invention.

FIG. 5 is a diagram showing the structure of a semiconductor chip (with an incorporated capacitor) according to a fourth embodiment of the present invention.

FIG. 6 is a diagram showing the structure of a semiconductor module according to a fifth embodiment of the present invention.

FIG. 7 is a diagram showing the structure of an interposer used in the fifth embodiment of the present invention.

FIG. 8 is a diagram showing the structure of a semiconductor module according to a sixth embodiment of the present invention.

FIG. 9 is a diagram showing the structure of a semiconductor chip according to a seventh embodiment of the present invention.

FIG. 10 is a diagram showing the structure of a semiconductor chip according to an eighth embodiment of the present invention.

FIG. 11 is a diagram showing the structure of a semiconductor module according to a ninth embodiment of the present invention.

FIG. 12 is a diagram showing the structure of a semiconductor module according to a tenth embodiment of the present invention.

FIG. 13 is a diagram showing the structure of a semiconductor module according to an eleventh embodiment of the present invention.

FIG. 14 shows pin layout tables of a conventional CPU.

FIG. 15 is a diagram showing the structure of a conventional CPU.

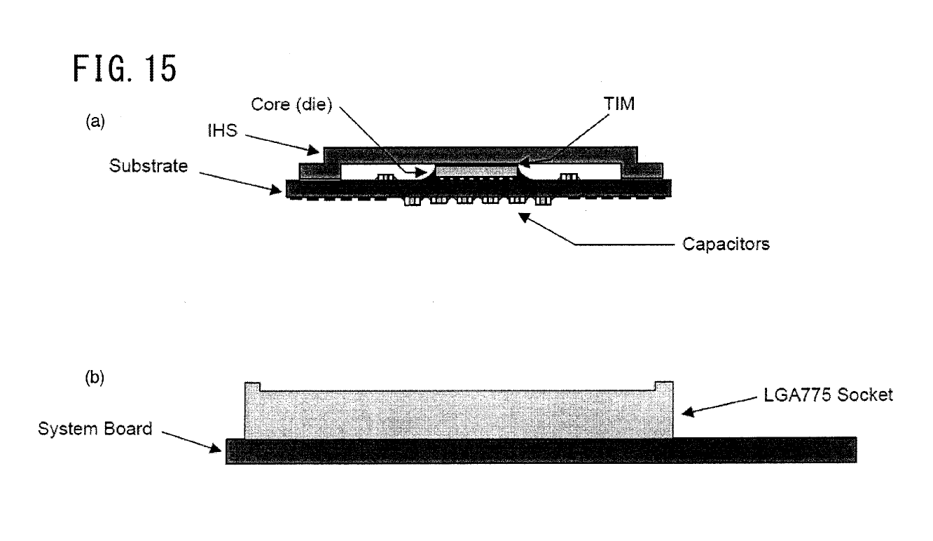

### EMBODIMENTS FOR CARRYING OUT THE INVENTION

Hereinafter, a semiconductor chip and a semiconductor device, and a semiconductor module carrying the same according to embodiments of the present invention will be explained in detail with reference to the accompanying drawings.

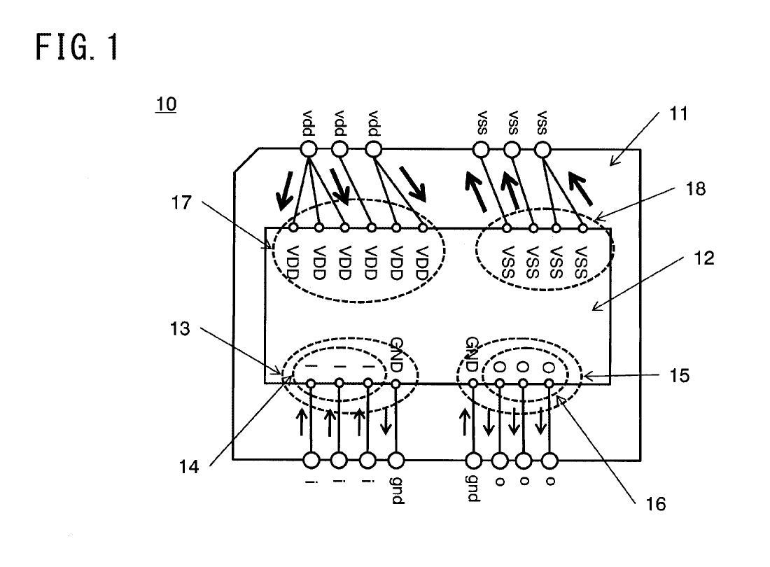

FIG. 1 is a diagram showing the internal connections of a semiconductor device. In FIG. 1, 10 denotes a semiconductor device mounted in a package 11, and 12 denotes a semiconductor chip. The semiconductor chip 12 is electrically connected to the terminals of the package 11 with bonding wires or the like.

In FIG. 1, 13 denotes a terminal group of an input signal system, which is formed by input signal current inflow terminals 14 (which are denoted by I) and input signal current outflow terminals (which are denoted by GND). The arrows indicate the direction of flow of the respective currents. 15 denotes a terminal group of an output signal system, which is formed by output signal outflow terminals 16 (which are denoted by O) and output signal inflow terminals (which are denoted by GND). With the input signal system, since the currents are comparatively smaller, one current outflow terminal is used in common for a plurality of current inflow terminals. This situation is applicable to the output signal system also. Further, the terminals GND included in the terminal groups 13 and 15 may be commonized by the terminals (which are denoted by gnd) of the package. 17 denotes supply current inflow terminals (which are denoted by VDD) and 18 denotes supply current outflow terminals (which are denoted by VSS); they are connected to corresponding terminal groups (which are denoted by vdd and vss) of the package, respectively. The arrows indicate the direction of flow of the respective currents.

The terminals 17 and 18 are configured in such a way that one of the terminals of the package 11 is connected to a plurality of the terminals of the semiconductor chip 12. Such the configuration reflects the fact that the number of the terminals of the semiconductor chip 12 can be set large because the arrangement pitch of these terminals is small and that, in contrast, the number of the terminals of the package 11 is small because the arrangement pitch of these terminals is large. That is, if it is difficult to arrange the terminals of the package 11 so as to correspond to all the terminals of the semiconductor chi 12 (if so, the number of the terminals becomes large and the package size is becomes large and as a result, the semiconductor device becomes large), the interconnection method shown in FIG. 1 is adopted. Further, in general, the terminals denoted by VSS of the semiconductor chip 12 and the terminals denoted by gnd are the same as the semiconductor substrate forming the semiconductor chip 12 in many cases. In this specification, since the currents flowing into the semiconductor chip 12 and the currents flowing out from the semiconductor chip 12 play an important role in configuration, they are denoted separately for convenience.

In this specification, in the configuration shown in FIG. 1, the terminals 14 into which the input signal currents inflow (which are denoted by “I” in the figure) and the terminals 16 from which the output signal currents outflow (which are denoted by “0” in the figure) are termed a “first terminal group”. In addition, the terminals from which the input signal currents that have flowed into the terminals 14 outflow and the terminals to which the output signal currents that have flowed out from the terminals 16 (both of which are denoted by “gnd” in the figure) are termed a “second terminal group”. Moreover, the terminals 17 are termed a “third terminal group” and the terminals 18 are termed a “fourth terminal group”.

In FIG. 1, all the terminal groups of the semiconductor chip are disposed on one plane of the semiconductor chip. On the other hand, with the semiconductor chip according to the present invention, the terminal groups through which large currents flow (the “third terminal group” and the “fourth terminal group”) are disposed on one plane of the semiconductor chip and the terminal groups of the input/output signals system (the “first terminal group” and the “second terminal group”) are disposed on the other plane of the semiconductor chip. This is the feature of the present invention.

### First Embodiment

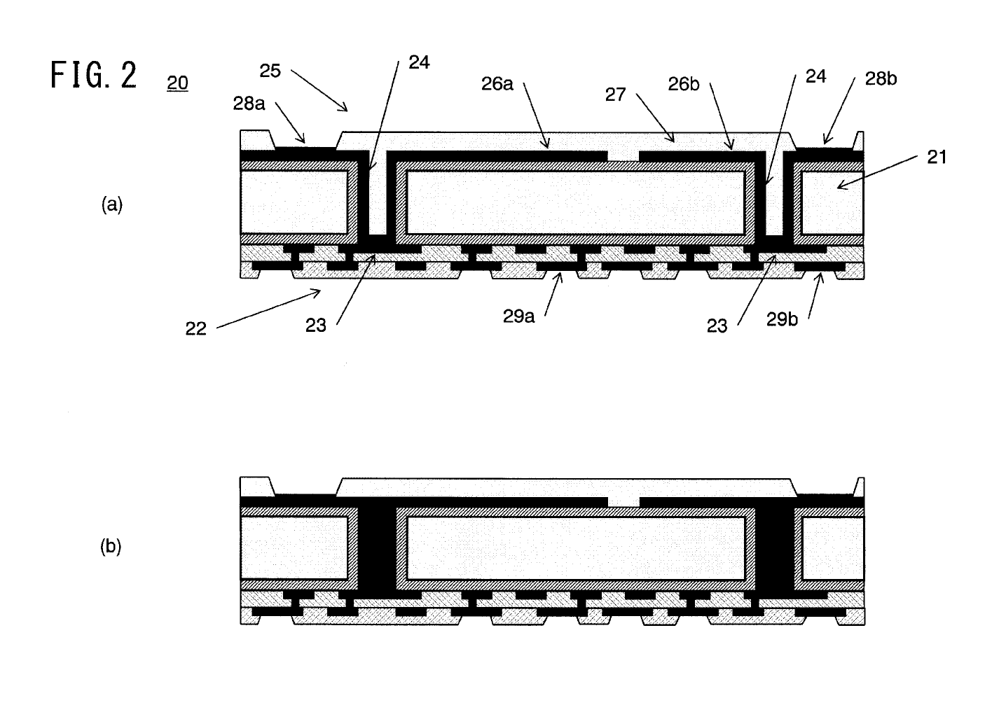

FIG. 2 is a diagram showing the structure of a semiconductor chip 20 according to a first embodiment of the present invention.

In FIG. 2(a), 21 denotes a semiconductor substrate, where the lower side of this figure is a first main surface 22. Electronic circuits (not shown) are integrated on the first main surface 22 and a two-layered wiring layer is disposed on the surface thereof. Such the “two-layered wiring layer” is only an example and it may be formed by three or more layers. In this semiconductor substrate, through wirings (which are also referred to as through electrodes) 24 are formed to penetrate through the substrate 21 and to be connected to a designated layer that forms the wiring layer 23. The through wirings 24 are connected to wiring layers 26a and 26b disposed on a second main surface 25 of the semiconductor substrate. In this figure, the number of the wiring layer 26a is one and the number of the wiring layer 26b is also one; however, these numbers are not limited to this and they may be two or more. The through wirings 24 and the wiring layers 26a and 26b are electrically insulated from the semiconductor substrate by way of an insulating film or the like. The wiring layers 26a and 26b are covered with an insulating layer 27. Openings 28a and 28b are formed in the specified areas of the insulating layer 27. These openings 28a and 28b are used, for example, as bonding pads for electrically connecting the semiconductor chip 20 to the package or an external circuit. The area for the opening 28a corresponds to the “third terminal group” and the area for the opening 28b corresponds to the “fourth terminal group”. Moreover, openings 29a and 29b are formed in the two-layered wiring layer 23. These openings 29a and 29b serve as, for example, the areas on which balls of a ball grid array are placed in electrical connection to the package or the external circuit. The area for the opening 29a corresponds to the “first terminal group” and the area for the opening 29b corresponds to the “second terminal group”.

In the configuration shown in FIG. 2, the wiring layers 26a and 26b are depicted as “always necessary” in the wiring layers 26a and 26b. However, the present invention is not limited to this. For example, the wiring layer 26a (or 26b) in which the opening 28a (or 28b) is not formed may be disposed and the wiring layer 26a (or 26b) may have only electric wiring function.

In the embodiment shown in FIG. 2(a), the “input/output signal system” constituting the electronic circuits is connected to the package or an external circuit through the openings 29a and 29b, and the “power supply circuit system” is connected to the package or an external circuit through the openings 28a and 28b. If this is described in more detail,

Opening 28a (the “third terminal group”): the terminals through which the supply currents flow into the semiconductor chip;

Opening 28b (the “fourth terminal group”): the terminals through which the supply currents flow out from the semiconductor chip;

Opening 29a (the “first terminal group”): the terminals through which the input signals flow into the semiconductor chip, or the terminals through which the output signals flow out from the semiconductor chip; and

Opening 29b (the “second terminal group”): the terminals through which the input signals flow out from the semiconductor chip, or the terminals through which the output signals flow into the semiconductor chip.

This situation can be realized by appropriately designing the wirings from the electronic circuits mentioned above.

In FIG. 2(a), an example where the thickness of the through wirings 24 is small and the insulating layer 27 enters the areas of the through wirings 24 is shown. On the other hand, in FIG. 2(b), an example where the thickness of the through wirings 24 is sufficiently large and the insulating layer 27 is located only on the second main surface 25 is shown. Since the through wirings 24 serve as current paths through which the large supply currents flow in or flow out by way of the through openings 28a and 28b, the impedance of the current paths needs to be low in such a way that voltage drop or the like does not occur. (For example, it is necessary that the thickness of the through wiring 24 is made large or the occupation area of the through wiring 24 is enlarged.) From this point of view, it can be said that the example of FIG. 2(b) is more preferred than the example of FIG. 2 (a). Moreover, by using a low resistivity material for the through wirings 24, the impedance of the above-described current paths can be lowered more effectively. If a low resistivity material such as copper is used, the thermal conductivity can be increased and therefore, the heat generated in the electronic circuits (not shown) disposed on the side of the first main surface 22 is effectively dissipated to the side of the second main surface 25.

In the semiconductor chip 20 of the first embodiment, the first terminal group and the second terminal group are placed on the first main surface 22, where the input signal inflow terminals or the output signal outflow terminals are defined as the first terminal group and the input signal outflow terminals or the output signal inflow terminals are defined as the second terminal group. Moreover, the third terminal group and the fourth terminal group are placed on the second main surface 25, where the supply current inflow terminals are defined as the third terminal group and the supply current outflow terminals are defined as the fourth terminal group. On the other hand, since the aforementioned electronic circuits are formed on the first main surface 22, it is essential for part of the wirings of these electronic circuits to be extended from the first main surface 22 to the second main surface 25. Such the electric connection is realized by the through wirings 24.

Because of the configuration of the first embodiment, the terminal group (which is also the current paths) through which large currents flow and the terminal group through which the input/output signals flow can be disposed separately on the two sides of the semiconductor chip 20. By optimizing the configurations of the terminal group through which large currents flow and the through wirings 24 (for example, by decreasing the impedance as low as possible), malfunctions (for example, drop and fluctuation of the supply voltage) induced by the power supply system can be avoided and at the same time, the heat dissipation effect can be enlarged even if the number of the terminals forming the aforementioned terminal groups.

### Second Embodiment

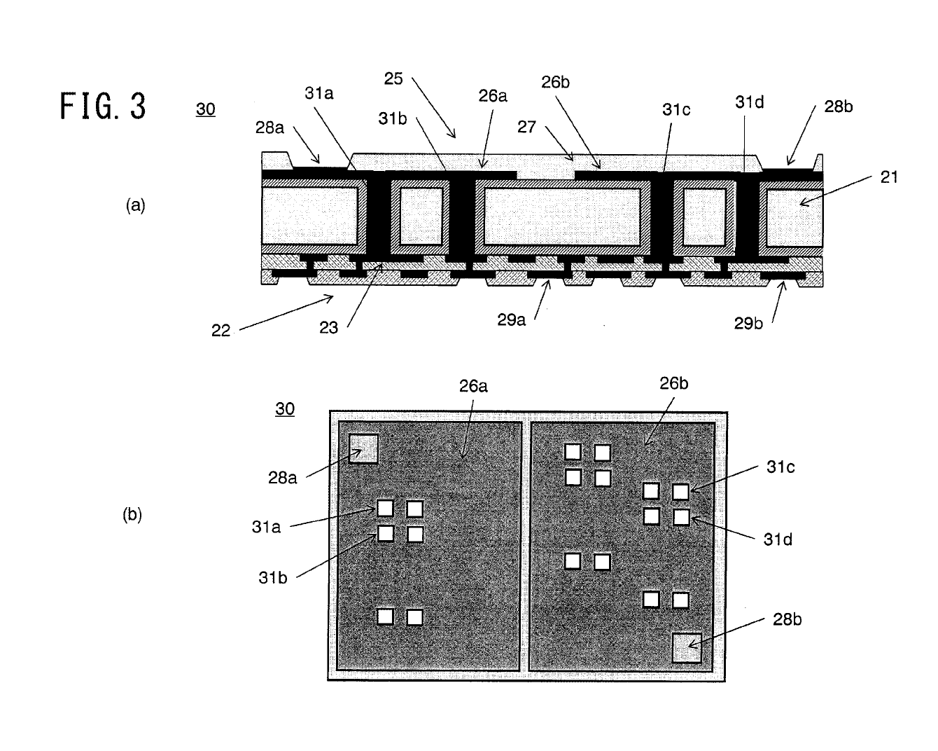

FIG. 3 is a diagram showing the structure of a semiconductor chip 30 according to the second embodiment of the present invention. In FIG. 3, the same numbers as those shown in FIG. 2 denote the same structural elements.

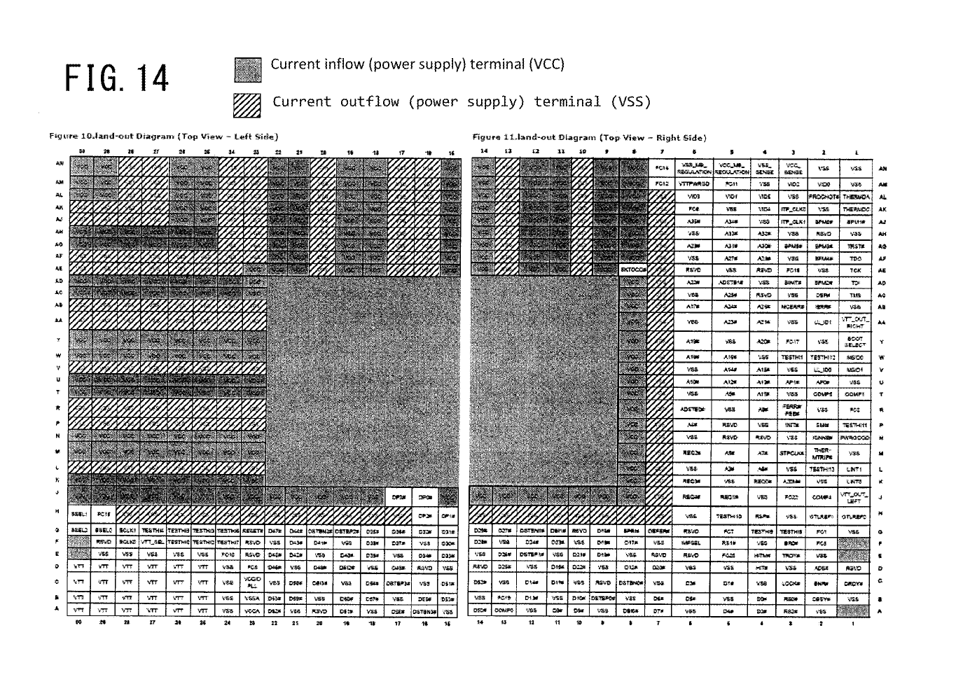

In FIG. 3(a), 31a and 31b denote through wirings, which are connected to the wiring layer 26a. 31c and 31d also denote through wirings, which are connected to the wiring layer 26b. In FIG. 3(a), the aforementioned through wirings (31a and so on) are arranged at a plurality of positions on the designated wiring layers 23 that constitutes the electronic circuits and the two-layered wiring layer, and are connected to the common wiring layer 26a or 26b. Since the electronic circuits that constitute the semiconductor chip contain the aforementioned wiring layers (23) which are at the same potential, the number of the terminals of this semiconductor chip can be reduced substantially by communizing the aforementioned wiring layers by the wiring layers 26a and 26b or the like. Such the situation is particularly effective in the case of a semiconductor chip having a lot of supply current inflow terminals (or supply current outflow terminals) like the conventional example shown in FIG. 14.

FIG. 3(b) is a plan view from the second main surface of the semiconductor chip of FIG. 3(a). In this figure, the same numbers as those shown in FIG. 3(a) denote the same structural elements.

FIG. 3(b) shows a case where the wiring layers 26a and 26b are formed to cover the almost entirety of the second main surface of the semiconductor chip. In such the configuration, the heat generated in the electronic circuits formed on the first main surface side is guided to the aforementioned wiring layers by way of the through wirings (31a, 31b, 31c, 31d) and dissipated from the wide area of the same wiring layers. Moreover, by forming these wiring layers by a material with a high thermal conductivity such as copper and increasing the thicknesses of these wiring layers, a further heat dissipation effect can be realized.

Furthermore, in the second embodiment of FIG. 3, by obtaining a wafer (or chip) on which electronic circuits are formed and applying a post-process to the wafer (or chip) thus obtained, the configuration of FIG. 3 can be realized.

In general, in a wafer obtained through a semiconductor process line, a chip all the terminals of which are arranged on the aforementioned first main surface side is included. Since the configuration of FIG. 3 can be realized by forming through wirings in this wafer, a chip of “general purpose specification” can be remade to a chip of “individual specification” which is matched to an application system to which the chip is mounted. Due to such the advantage, the “terminal number” which is obtained by implementing a chip of “general purpose specification” as it is on the system can be reduced drastically. In addition, this reduction of the terminal number will reduces the area required for implementation also.

### Third Embodiment

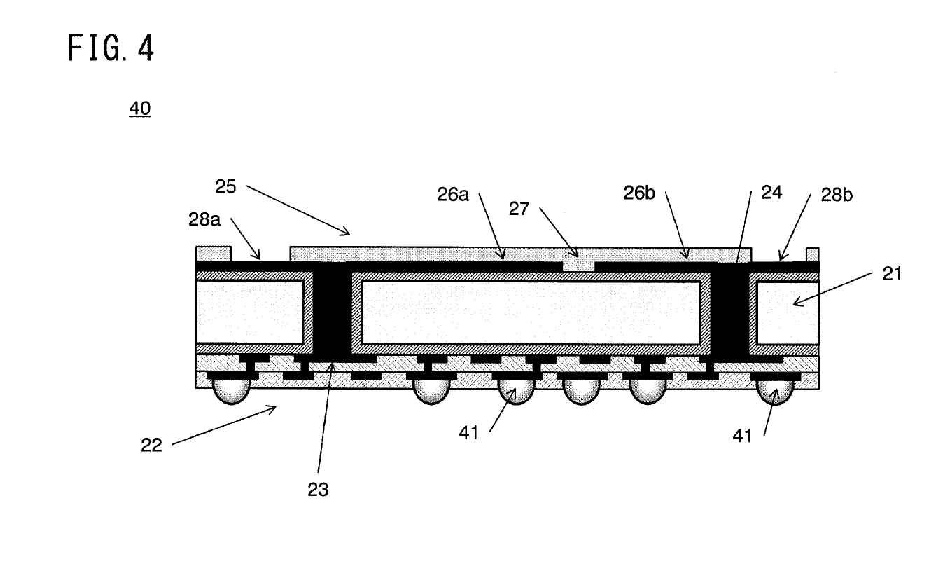

FIG. 4 is a diagram showing the structure of a semiconductor device according to the third embodiment of the present invention, on which the semiconductor chip 20 shown in FIG. 2 is mounted. In FIG. 4, the same numbers as those shown in FIG. 3 denote the same structural elements. In FIG. 4, 40 denotes the semiconductor devices, and 41 denotes a conductive ball which is disposed in the opening 29a or 29b and which constitutes a ball grid array (BGA). The ball 41 is made of a metal material such as solder (preferably, lead-free solder). In addition, in this figure, a device called “chip size BGA package” is shown as a configuration example of the “semiconductor device”. The semiconductor device of FIG. 4 is similar in structure to the “semiconductor chip” shown in FIG. 2. However, the semiconductor chip of FIG. 2 is in the state of being cut out from a wafer and no protective film for enhancing the environmental resistance is provided. Unlike this, the semiconductor device of FIG. 4 comprises protective films (not shown) formed on the surfaces (the first and second main surfaces) and the sides (the sidewalls of the chip formed by scribing) thereof, which is different from the chip of FIG. 2 at this point. In addition, the “semiconductor device” shown in FIG. 4 is also referred to as “chip size package”, and has a shape which can be distributed as a product.

In the third embodiment also, the “first terminal group” and the “second terminal group” through which the input/output signal system signals flow are disposed on the first main surface side of the semiconductor chip, and the “third terminal group” and the “fourth terminal group” through which large currents flow are disposed on the second main surface side of the semiconductor chip.

### Fourth Embodiment

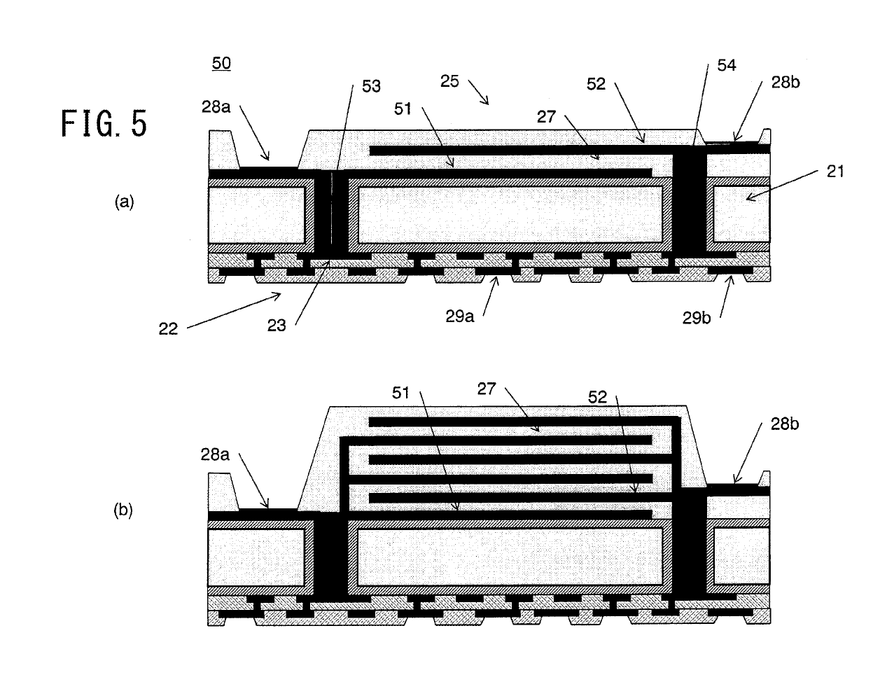

FIG. 5 is a diagram showing a semiconductor chip according to the fourth embodiment of the present invention. In FIG. 5, the same numbers as those shown in FIG. 2 denote the same structural elements. In FIG. 5(a), the number of opening 28a (which constitutes the third terminal group) is one and the number of the opening 28b (which constitutes the fourth terminal group) is also one; however, these numbers are not limited to this. 50 denotes an improved semiconductor chip, 51 denotes a first conductive layer, and 52 denotes a second conductive layer. The semiconductor chip 51 is disposed on the second main surface and electrically connected to the “at least one terminal constituting the third terminal group” (which corresponds to 28a) and the through wiring 53. The second conductive layer 52 is disposed on the second main surface side and electrically connected to the “at least one terminal constituting the fourth terminal group” (which corresponds to 28b) and the through wiring 54. Further, the first and second conductive layers 51 and 52 are disposed opposite to each other by way of the insulating layer 27. In this structure, the conductive layers 51 and 52 serve as opposite electrodes and the insulating layer 27 serves as a dielectric, forming a capacitor.

Between the “supply current inflow terminal (for example, the opening 28a)” and the “supply current outflow terminal (for example, the opening 28b)”, a capacitor with a large capacitance for absorbing fluctuation of the supply voltage and a capacitor with a small capacitance absorbing the noise such as a switching noise induced by the supply current varying at high speed are connected in parallel in many cases. Since the capacitor with a large capacitance is unable to be disposed on the surface of the semiconductor chip, it is usually disposed in the peripheries of the terminals of the semiconductor device or semiconductor module on which the semiconductor chip is mounted. On the other hand, it is preferred that the “small-capacitance capacitor” is disposed near the semiconductor chip as much as possible from the viewpoint of noise reduction. In this embodiment, the “small-capacitance capacitor” is configured by utilizing the wiring layers (which correspond to 51 and 52 in FIG. 5) disposed on the second main surface side that constitute the semiconductor chip. For this purpose, the wiring layers 51 and 52 are opposed to each other by way of the insulating layer 27. In addition, the capacitance of the “small-capacitance capacitor” is determined in proportion to the spatially overlapped area between the wiring layers 51 and 52, is in inverse proportion to the distance between the wiring layers 51 and 52 (which is determined by the insulating layer 27), and is in proportion to the dielectric constant of the insulating layer 27.

In the configuration shown in FIG. 5 (a), the number of the “small-capacitance capacitor” is one; however, the present invention is not limited this. The over two “small-capacitance capacitors” may be disposed on the second main surface side of the semiconductor chip. Moreover, the “small-capacitance capacitor” is formed by two opposite electrodes (51 and 52); however, the present invention is not limited this. For example, like the configuration illustrated in FIG. 5 (b), a plurality of wiring layers are formed, and the odd-numbered wiring layers may be commonized to form the “first conductive layer” described above and the even-numbered wiring layers may be commonized to form the “second conductive layer” described above.

### Fifth Embodiment

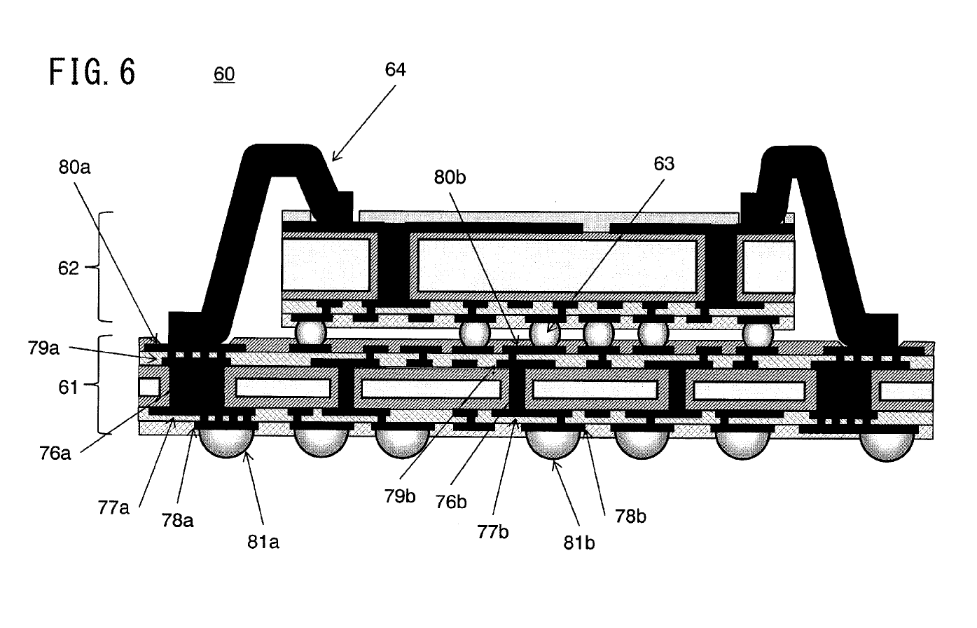

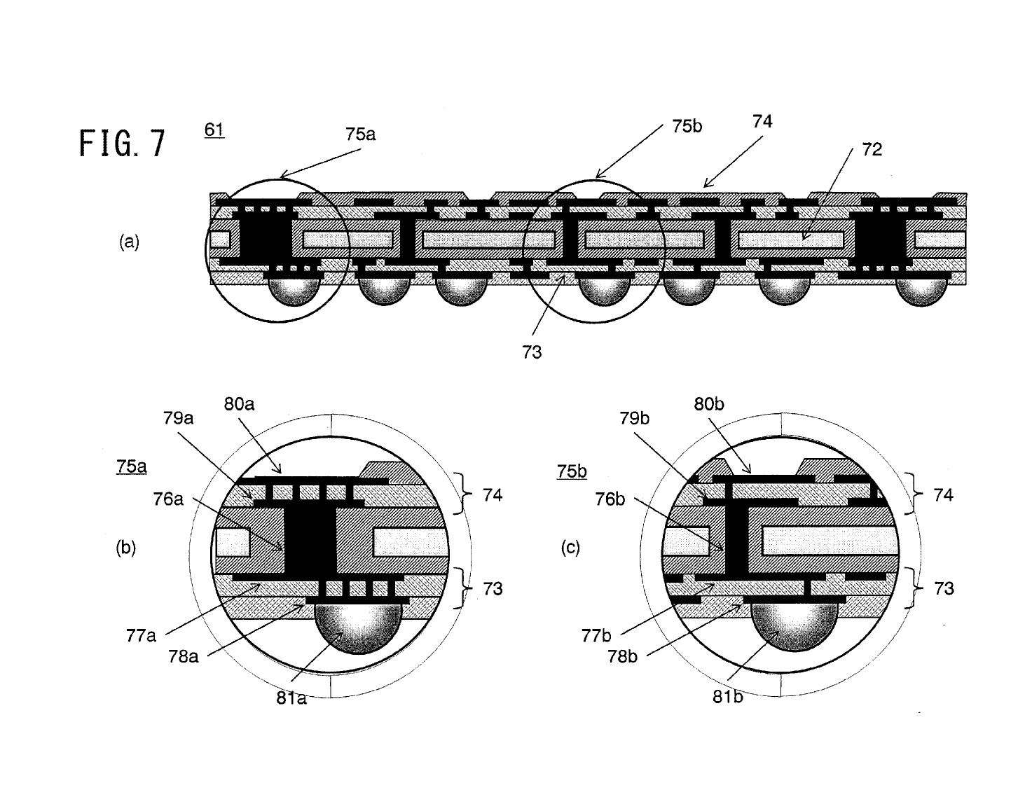

FIG. 6 shows a semiconductor module according to the fifth embodiment of the present invention, on which the aforementioned semiconductor device is mounted. In the same figure, the same numbers as those shown in FIG. 2 denote the same structural elements. In FIG. 6, 60 denotes a semiconductor module, 61 denotes an interposer, and 62 denotes the semiconductor chip 62 (see FIG. 2). The configuration of the interposer 61 is shown in FIG. 7 and the detail of the interposer 61 will be described in the following paragraphs.

In FIG. 7(a), the interposer 61 is made of a resin material or semiconductor material or the like. The interposer 61 made of a resin material is fabricated based on the printed circuit board technology, which is inexpensive, but has a limit about the pattern density of an electric wiring layer that can be placed on a surface or the like. For example, the formation of electric wiring layer patterns whose size is several micrometers or less is difficult. On the other hand, the interposer 61 made of a semiconductor material can be fabricated based on the highly developing fabrication technology of semiconductor integrated circuits and therefore, there is an advantage that the pattern density of electric wiring layers can be increased significantly. The “interposer” according to the present invention may be made of either a semiconductor material or a resin material, and furthermore, it may have a configuration obtained by combining a semiconductor material and a resin material. An example of such the configuration is that electric wiring layers formed by the semiconductor technology are disposed on the two sides (the first and second main surfaces) of the semiconductor substrate, and resin layers are laminated on the surfaces of the electric wiring layers thus formed so as to form a multi-layer printed circuit board by “resin material”.

In FIG. 7 (a), the interposer 61 formed from a semiconductor substrate is shown as an example. In this figure, 72 denotes a semiconductor substrate made of silicon or the like, and 73 and 74 denote electrical wiring layers disposed on the surface and back of the semiconductor substrate, respectively. Each of the electrical wiring layers 73 and 74 comprises “two layers”, and an interlayer wiring is formed between the two layers. However, the present invention is not limited to this. 75a and 75b denote through wiring regions in which the through wirings are formed, where the through wirings interconnect the electrical wiring layers respectively disposed on the two sides of the semiconductor substrate. Partially enlarged views of the through wiring regions are shown in FIG. 7(b) and FIG. 7 (c).

In FIG. 7(b), 77a and 78a denote two electric wiring layers formed on the back (the lower face in this figure) of the interposer 61, where interlayer wiring is performed along the thickness direction of the interposer 61. 79a and 80a denote two electric wiring layers formed on the surface (the upper face in this figure) of the interposer 61, where interlayer wiring is performed along the thickness direction of the interposer 61. 76a denotes a through wiring that connects electrically the electric wiring layers 79a and 77a. The cross-sectional area of the through wiring 76a is enlarged so as to allow a large current to flow; however, the present invention is not limited to this. Another method of increasing the permissible current value is “to dispose closely a plurality of thin through wirings, thereby electrically connecting the through wirings in parallel”. This method may be used for this purpose.

In FIG. 7(b), a plurality (four in this figure) of the interlayer wirings (wirings connecting 78a and 77a, or 79a and 80a) for the electric wiring layers are disposed to increase the allowable current value of the interlayer wirings. Further, as will be described later, the interlayer wiring 80a serves as a terminal for electrical connection to the semiconductor chip (62 in FIG. 6) mounted on the interposer 61. This terminal is connected to the “third terminal group” or “fourth terminal group” mentioned above by bonding wires or the like. On the other hand, the interlayer wiring 78a is a terminal for connecting the interposer 61 to an external circuit (not shown), on which a conductive ball 81a is disposed. If illustrating the interlayer wiring 78a with reference to FIG. 6, the interlayer wiring 78a serves as a terminal for connecting the “semiconductor module” to an external circuit. In this configuration as described in this paragraph, the allowable current value of the current path from the electric wiring layer 80a of the interposer 61 to the electric wiring layer 78a thereof can be set large.

In FIG. 7(c), 77b and 78b denote two electric wiring layers formed on the back (the lower face in this figure) of the interposer 61, where interlayer wiring is performed along the thickness direction of the interposer 61. 79b and 80b denote two electric wiring layers formed on the surface (the upper face in this figure) of the interposer 61, where interlayer wiring is performed along the thickness direction of the interposer 61. 76b denotes a through wiring that connects electrically the electric wiring layers 79b and 77b. In the case of FIG. 7(c), it is unnecessary to flow a large current (which are used for connection to the input/output signal system) and therefore, the cross-sectional area of the through wiring 76b need not be enlarged particularly. An example of the diameter of the through-hole wiring 76b is 5 to 20 micrometers. Further, in FIG. 7(c), it is unnecessary for the interlayer wirings (wirings for connecting 77b and 78b or 79b and 80b) of the electric wiring layer to be thick. An example of the diameter of the interlayer wiring is 5 to 20 micrometers. Further, as will be described later, the interlayer wiring 80b serves as a terminal for electrical connection to the semiconductor chip (62 in FIG. 6) mounted on the interposer 61. This terminal is connected to the “first terminal group” or “second terminal group” mentioned above by bonding wires or the like. On the other hand, the interlayer wiring 78b is a terminal for connecting the interposer 61 to an external circuit (not shown), on which a conductive ball 81b is disposed. If illustrating the interlayer wiring 78b with reference to FIG. 6, the interlayer wiring 78b serves as a terminal for connecting the “semiconductor module” to an external circuit.

Next, the structure of the semiconductor module 60 (fifth embodiment) obtained by mounting a semiconductor chip on the interposer 61 shown in FIG. 7 will be further described in detail below.

In FIG. 6, an example where the single semiconductor chip 62 is mounted on the interposer 61 is shown; however, the number of the semiconductor chips 62 to be mounted on the interposer 61 may be two or more. The semiconductor chip 62 is disposed in such a way that the first main surface is opposed to the side of the interposer 61, and the “first terminal group” and the “second terminal group” disposed on the first main surface side are the conductive balls 63 and are electrically connected to the interposer 61. The “third terminal group” and the “fourth terminal group” disposed on the second main surface of the semiconductor chip 62 are electrically connected to the interposer 61 by connecting means such as a bonding wire 64. Since a large current flows through the bonding wire 64, the thickness of the bonding wire 64 needs to be large. In FIG. 6, the bonding wire 64 with a large diameter is illustrated; however, the permissible current value may be increased by arranging a plurality of the bonding wires 64 with a small diameter in parallel. The large current for the power supplying flows through the current path of the external circuit (not shown)→81a→78a→77a→76a→79a→80a→64, and finally flows into the semiconductor chip 62. (This current flows out from the semiconductor chip 62 through the same current path in the reverse direction). On the other hand, the input/output signal currents flow through the current path of the external circuit (not shown)→81b→78b→77b→76b→79b→80b→63, and finally flow into the semiconductor chip 62. (This current flows out from the semiconductor chip 62 through the same current path in the reverse direction).

### Sixth Embodiment

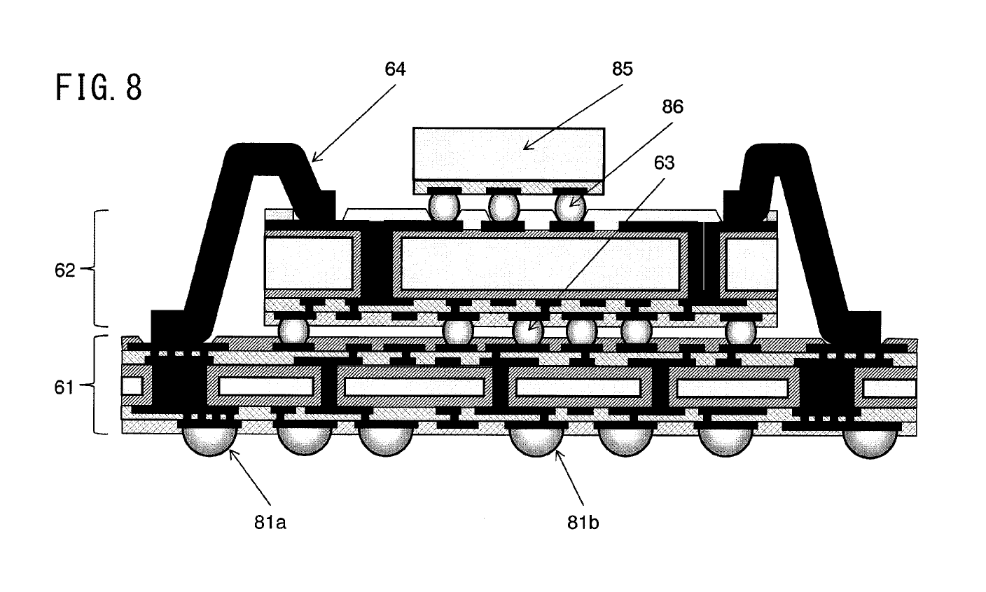

FIG. 8 is a diagram showing the structure of a semiconductor module according to the sixth embodiment of the present invention. In FIG. 8, the same numbers as those shown in FIG. 6 denote the same structural elements.

In FIG. 8, a semiconductor chip 62 is mounted on the interposer 61, and a second semiconductor chip 85 is mounted on the semiconductor chip 62. The second semiconductor chip 85 is electrically connected to the semiconductor chip 62 by way of conductive balls 86. The second semiconductor chip 85 is, for example, a power supply IC, and has the function of stepping-down (e.g., to 1.5 V from 3.3 V) the supply voltage which is fed through the bonding wires 64 and supplying the step-downed supply voltage to the semiconductor chip 62.

The second semiconductor chip 85 is not limited to a semiconductor chip and may be a packaged semiconductor device or an electronic component such as a resistor, capacitor and coil. In particular, when the semiconductor device is a surface-mount type device of a ball grid array, electrical connection can be performed by using conductive balls as shown in FIG. 8.

In the configuration of FIG. 8, on the second main surface side of the semiconductor chip 62, the “third terminal group” and the “fourth terminal group” for power supplying are disposed, and furthermore, a “power supply system” formed by the second semiconductor chip (or a second semiconductor device) is disposed also. In the configuration of FIG. 8, the number of the second semiconductor chip is one; however, the two or more second semiconductor chips or second semiconductor devices or the second electronic parts may be mounted.

FIG. 8 shows the case where the number of the second semiconductor chip (62) is one; however, this number may not always be one. Two or more semiconductor chips may be mounted on the interposer 61. Moreover, in the configuration including two or more semiconductor chips, the second semiconductor chip or the second semiconductor device or the second electronic part may be mounted on selected one or more semiconductor chips or all the semiconductor chips.

### Seventh Embodiment

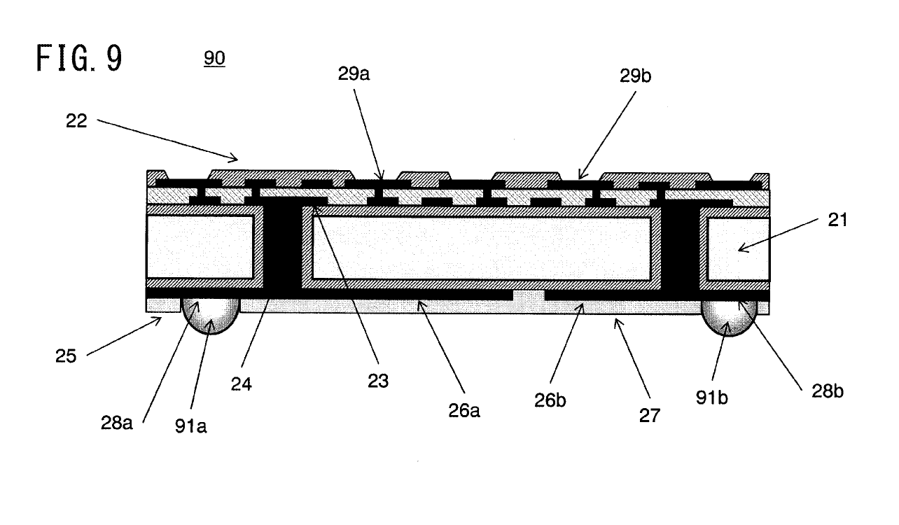

FIG. 9 is a diagram showing the structure of a semiconductor chip according to the seventh embodiment of the present invention. In FIG. 9, the same numbers as those shown in FIG. 2 denote the same structural elements; however, the semiconductor chip is shown upside down. In FIG. 9, 90 denotes a semiconductor chip, 91a and 91b denote conductive balls disposed respectively in the openings 28a and 28b.

In the seventh embodiment, it is configured in such a way that a large current for power supplying flows into the “third terminal group” (e.g., 28a) and the “fourth terminal group” (e.g., 28b) disposed on the second main surface side of the semiconductor chip 90 by way of the conductive balls (91a and 91b). Moreover, it is configured in such a way that signal currents for the input/output system flow into the “first terminal group” (e.g., 29a) and the “second terminal group” (e.g., 29b) disposed on the first main surface side of the semiconductor chip 90 by way of bonding wires or the like (not shown).

In the configuration shown in FIG. 9, the current path through which a large current flows is given by the through wirings 24→the wiring layer 26a (or 26b)→the conductive ball 91a (or 91b). Therefore, there is an advantage that this current path can be shortened (wiring can be performed shorter than the bonding wires) compared with the configuration shown in FIGS. 2 to 4.

### Eighth Embodiment

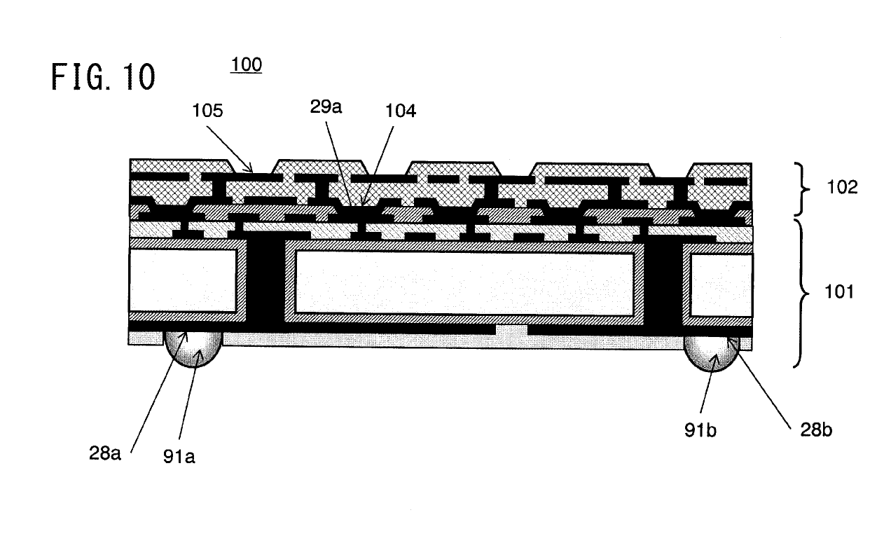

FIG. 10 is a diagram showing the structure of a semiconductor chip according to the eighth embodiment of the present invention. In FIG. 10, the same numbers as those shown in FIG. 9 denote the same structural elements.

In FIG. 10, 100 denotes an improved semiconductor chip, which is formed by a chip element denoted by 101 and an electric wiring layer denoted by 102. In addition, the chip element 101 is the same as the structure described in FIG. 9. The electric wiring layer 102 is disposed on the surface of the chip element 101 (which is the first main surface of the semiconductor chip mentioned above), and is composed of a wiring layer 104 and a wiring layer 105 stacked on the upper side of the wiring layer 104. Furthermore, the wiring layers 104 and 105 are electrically connected in the vertical direction of FIG. 10 (which is interlayer wiring). The wiring layer 104 is electrically connected to the opening (29a, for example) that constitutes the “first terminal group” or the “second group”. The wiring layer 102 rewires the “first terminal group” or the “second group” disposed on the wiring layer 101. Such the rewiring makes it possible to optimize the wiring relating to the input/output signals for each application field in the application of the improved semiconductor chip. As a result, for example, the number of “the first terminal group” or the “second terminal group” can be reduced. In FIG. 10, the electric wiring layer is a two-layer wiring layer; however, the present invention is not limited to this.

The eighth embodiment shown in FIG. 10 is realized by (1) disposing an electric layer formed by at least one layer on the first main surface of the semiconductor chip 90, and (2) electrically connecting the first and second terminal groups to the electric wiring layer.

### Ninth Embodiment

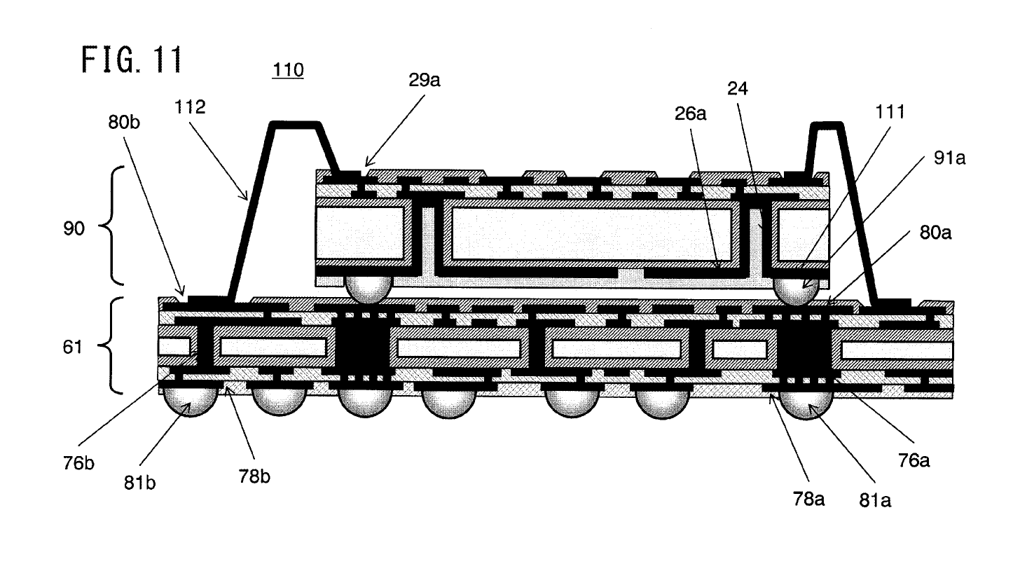

FIG. 11 is a diagram showing the structure of a semiconductor module according to the ninth embodiment of the present invention. This semiconductor module has the structure obtained by mounting the semiconductor chip shown in FIG. 9 or on the interposer shown in FIG. 7. In FIG. 10, the semiconductor chip of FIG. 9 is shown. In FIG. 10, the number of the semiconductor chip mounted on the interposer is one; however, two or more semiconductor chips may be mounted. In FIG. 11, the same numbers as those shown in FIGS. 7 and 9 denote the same structural elements.

In FIG. 11, 110 denotes a semiconductor module, which is formed by the aforementioned interposer 61 (FIG. 7) and the aforementioned semiconductor chip 90 (FIG. 9). The semiconductor chip 90 is mounted in such a way that the second main surface of the chip 90 faces the interposer 61. The “third terminal group” or the “fourth terminal group” (111, for example) disposed on the second main surface of the chip 90 is electrically connected to the electric wiring layer 80a constituting the interposer 61 by the conductive ball 91a. The electrical connecting means of the semiconductor chip 90 and the interposer 61 is not limited to the grid array by the conductive balls.

The “first terminal group” or the “second terminal group” (29a, for example) disposed on the first main surface of the chip 61 is electrically connected to the electric wiring layer 80b by the connecting means such as the bonding wires 112. Since the currents for the input/output signal system flow through the bonding wires 112, the bonding wires 112 need not always be thick ones for large currents. Bonding wires having a diameter of 50 to 200 micrometers can be used. (1) The semiconductor module 110 comprises the interposer 61 and the semiconductor chip 90 as its structural elements; (2) one or more semiconductor chips including the semiconductor chip 90 are mounted on the interposer 61; (3) the second main surface of the semiconductor chip 90 is disposed on the side of the interposer 61; (4) the third terminal group and the fourth terminal group are electrically connected to the interposer 61 by connection means comprising a ball grid array; and (5) the first terminal group and the second terminal group are electrically connected to the interposer 61 by connection means comprising wire bonding.

In the ninth embodiment, a current path for power supply through which a large current flows is formed on the lower side of the semiconductor chip 90 (which is the side opposite to the interposer 61 and is the second main surface also), and this current path is electrically connected to the interposer 61 by way of the conductive balls or the like. This current path is 81a→78a→76a (thick through wiring)→80a→91a→111→26a→24. On the other hand, a current path for the input/output signal system through which a small current flows is formed on the upper side of the semiconductor chip 90 (which is the side apart from the interposer 61 and is the first main surface also), and this current path is electrically connected to the interposer 61 by way of the bonding wires or the like. This current path is 81b→78b→76b (thin through wiring)→80b→112→29a.

### Tenth Embodiment

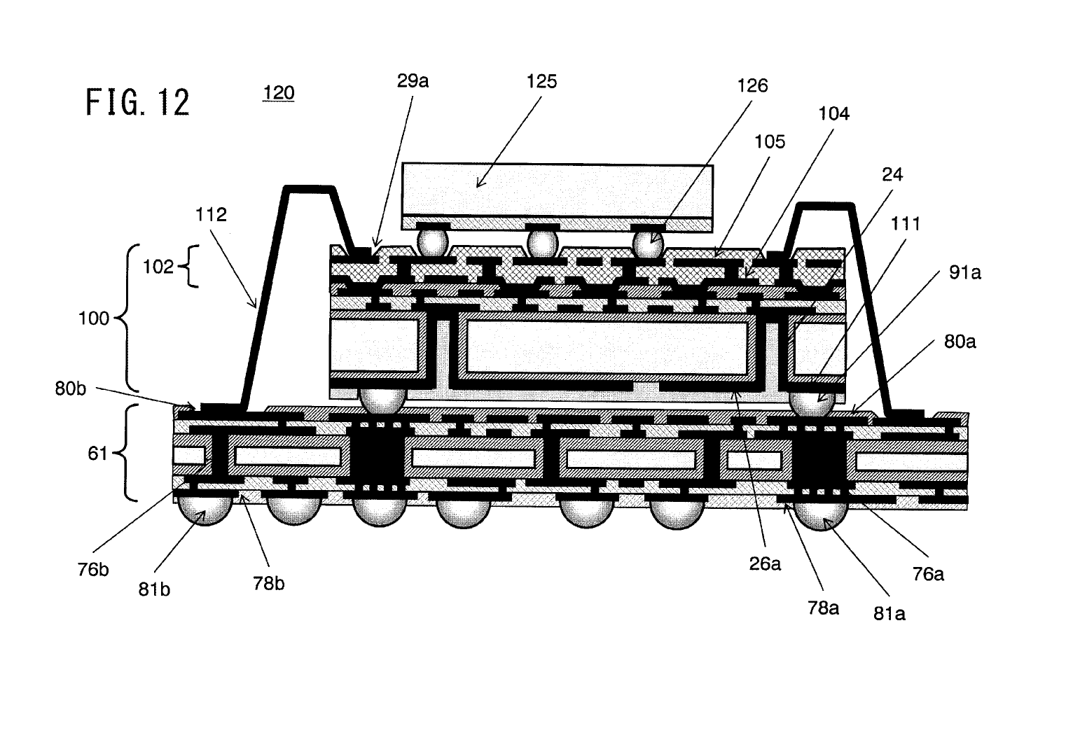

FIG. 12 is a diagram showing the structure of a semiconductor module according to the tenth embodiment of the present invention. This semiconductor module has the structure obtained by mounting the semiconductor chip (which is the “third semiconductor chip”) shown in FIG. 10 on the interposer shown in FIG. 7, and mounting a fourth semiconductor chip on the surface of the semiconductor chip (upper side in the figure). In FIG. 11, the number of the third semiconductor chip mounted on the interposer is one; however, two or more semiconductor chips may be mounted. In FIG. 12, the same numbers as those shown in FIGS. 7 and 10 denote the same structural elements.

In FIG. 12, 120 denotes a semiconductor module, which includes as its structural elements the aforementioned interposer 61 (FIG. 7) and the aforementioned third semiconductor chip 100 (FIG. 10). The semiconductor chip 100 is disposed to face the interposer 61 is the second main surface. The “third terminal group” or the “fourth terminal group” (111, for example) disposed on the second main surface of the chip 100 is electrically connected to the electric wiring layer 80a constituting the interposer 61 by the conductive ball 91a. The electrical connecting means of the semiconductor chip 100 and the interposer 61 is not limited to the grid array by the conductive balls.

An electric wiring layer 102 consisting of wiring layers 104 and 105 is disposed on the upper surface of the semiconductor chip 100 (the first main surface side). The fourth semiconductor chip 125 is mounted on the electric wiring layer 102 and is electrically connected to the layer 102 by way of conductive balls 126. That is, as described in the eighth embodiment (FIG. 10), the “first terminal group” or the “second terminal group” disposed on the first main surface of the semiconductor chip 100 is rewired by the electric wiring layer 102 and electrically connected to the fourth semiconductor chip 125. As a result, for example, the number of the “first terminal group” or the “second terminal group” can be decreased. In FIG. 12, the number of the electric wiring layer 102 is a two-layer wiring is one; however, the present invention is not limited to this.

In FIG. 12, the case where the “fourth semiconductor chip” is mounted is shown; however, the “fourth semiconductor device or the fourth electronic part” may be mounted instead of a semiconductor chip. Furthermore, in the case where the “fourth semiconductor chip” is a surface-mount type with a grid array, the electrical connection to the electrical wiring layer 102 can be performed with conductive balls and therefore, this case is more preferred.

In the tenth embodiment of FIG. 10, the number of the “fourth semiconductor chip 125 (or the semiconductor device or the electronic part) is one; however, two or more semiconductor chips or semiconductor devices or electronic parts may be mounted. For example, peripheral circuit IC (peripheral IC) such as line drivers, multiplexers, interfaces (for example, a wireless transmission/reception circuit), or analog-to-digital converters, operational amplifiers, sensors such as temperature sensors, power supply circuits (for example, voltage step-up circuits, not necessarily a large capacity), or combinations thereof. In addition, capacitors for power supply voltage stabilization or noise absorption, inductors in step-up circuits or radio circuits, or thermistors for temperature detection may be mounted.

### Eleventh Embodiment

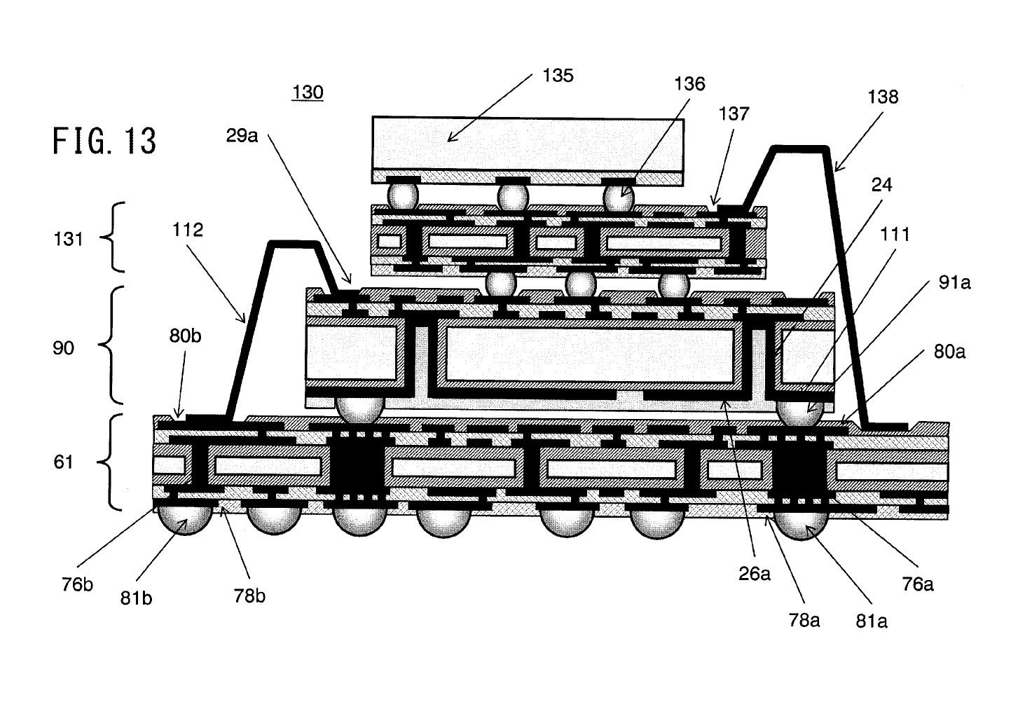

FIG. 13 is a diagram showing the structure of a semiconductor module according to the eleventh embodiment of the present invention. This semiconductor module has the configuration obtained by mounting the semiconductor chip 90 shown in FIG. 9 on the interposer 61 shown in FIG. 7, and further mounting a fifth semiconductor chip on the surface of the chip 90 by way of a second interposer. In FIG. 13, the same numbers as those shown in FIGS. 7 and 9 denote the same structural elements.

In FIG. 13, 131 denotes a second interposer, which is electrically connected to the semiconductor chip 90 (which is the third semiconductor chip). 135 denotes a “fifth semiconductor chip”, which is electrically connected to the second interposer 131 by way of conductive balls 136 or the like. A bonding wire 138 is provided to extend from the opening 137 of the second interposer 131 and is electrically connected to the interposer 61. In such the configuration, as a substitute for the electric wiring layer (102 in FIG. 12) of the semiconductor chip 100 shown in FIG. 12, the second interposer 131 is disposed. The material of the second interposer 131 may be a semiconductor material such as silicon or a resin material, or a combination of them.

In the eleventh embodiment of FIG. 13, the second interposer 131 is used as a substitute for the aforementioned electric wiring layer. According to this configuration, the second interposer 131 can be formed in a separate process from the third semiconductor chip 90; therefore, as compared with the aforementioned electric wiring layer, there are advantages that (1) the restrictions required by post-processing of the semiconductor chip 90 can be avoided, and (2) design flexibility of the electric wiring layer disposed on the front and back surfaces of the second interposer 131 can be increased. For example, in (1), if the electrical wiring layer 102 is formed by post processing, temperature, materials, and treatment atmospheres may be restricted in order not to degrade the characteristics of the semiconductor chip. Further, in (2), it may be difficult for the electric wiring layer 102 to be designed to satisfy the required specifications due to the number of the electric wiring layer 102 and pulling movement on the wires and so on. On the other hand, when the second interposer 131 is used, there is a disadvantage that the assembling steps of the semiconductor module are increased; however there are many advantages because design flexibility and process flexibility are greatly increased.

In FIG. 13, the configuration where the single semiconductor chip 135 is mounted over the single third semiconductor chip 90 is shown; however the present invention is not limited to this. For example, there are (1) a configuration that one or more semiconductor chips (90) are mounted on the interposer (61), (2) a configuration that one or more “second interposers” are mounted on one or more specified ones of the semiconductor chips, or (3) a configuration that one or more “fifth semiconductor chips or fifth semiconductor devices or fifth electronic parts” are mounted on one or more specified ones of the “second interposers”.

### INDUSTRIAL APPLICABILITY

According to the present invention, (1) a semiconductor chip or semiconductor device capable of “stable power supplying” can be realized even if the number of the terminals is small due to a terminal configuration with a large permissible current value and so on, (2) the noises which are mixed into the input/output signals from the wiring through which large currents flow can be reduced even during high-speed operation, (3) the connection reliability can be ensured due to reduction of the number of the terminals, (4) the area for implementation can be reduced by pin count reduction, and (5) the heat generated in the semiconductor chip can be dissipated effectively.

Therefore, by applying the present invention to the information processing field (e.g., application systems including GPUs or CPUs), the effects will be large. Further, by applying the semiconductor chip according to the present invention to a semiconductor module, original semiconductor modules having the function adapted to individual application systems can be easily realized. Therefore, if applied to the application systems such as data processing equipment, automotive equipment, and portable devices, it is possible to greatly contribute to weight reduction and miniaturization of these devices.

### DESCRIPTION OF REFERENCE NUMERALS

10, 40 semiconductor device
11 package
12, 20, 30, 50, 62, 90, 100, 135 semiconductor chip
13 terminals of input signal system
14 terminals into which input signal current flows (first terminal group)
15 terminals of output signal system
16 terminals from which output signal current flows (first terminal group)
17 terminals into which power supply current flows (third terminal group)
18 terminals from which power supply current flows (fourth terminal group)
21, 72 semiconductor substrate
22 first main surface
23, 26a, 26b, 104, 105 wiring layer
24, 31a, 31b, 31c, 31d, 53, 54, 76a, 76b through wiring
25 second main surface
27 insulating layer
28a, 28b, 29a, 29b openings
41, 63, 81a, 81b, 86, 91a, 91b, 126, 136 conductive ball
51, 52 conductive layer
60, 110, 120, 130 semiconductor module
61, 131 interposer
64, 112, 138 bonding wire
73, 74, 77a, 77b, 78a, 78b, 79a, 79b, 80a, 80b, 102 electrical wiring layer
75a, 75b through wiring region
85, 125, 135 semiconductor chip or semiconductor device or electronic part
101 chip element
111 terminals

1. A semiconductor chip on which electronic circuits are integrated, comprising:
a first terminal group comprising a terminal through which an input signal flows into the semiconductor chip and a terminal through which an output signal flows out from the semiconductor chip;
a second terminal group comprising a terminal through which an input signal flows out from the semiconductor chip and a terminal through which an output signal flows into the semiconductor chip;
a third terminal group comprising a terminal through which a power supply current flows into the semiconductor chip; and
a fourth terminal group comprising a terminal through which a power supply current flows from the semiconductor chip;
wherein the first terminal group and the second terminal group are placed on a first main surface of the semiconductor chip on which electronic circuits are integrated; and
the third terminal group and the second terminal group are placed on a second main surface of the semiconductor chip; wherein the second main surface is opposite to the first main surface.

2. The semiconductor chip according to claim 1, wherein at least one of the terminals constituting the third terminal group is connected to a first conductive layer;
at least one of the terminals constituting the fourth group is connected to a second conductive layer; and
the first conductive layer and the second conductive layer form a capacitor.

3. The semiconductor chip according to claim 1, wherein an electric wiring layer composed of at least one layer is placed on the first main surface of the semiconductor chip; and
the first terminal group and the second terminal group are electrically connected to the electric wiring layer.

4. A semiconductor module comprising an interposer and the semiconductor chip as structural elements; the module comprising:
at least one semiconductor chip including the semiconductor chip, mounted on the interposer;
wherein the first main surface of the semiconductor chip is opposed to the interposer;
the first terminal group and the second terminal group are electrically connected to the interposer by a connecting method including a ball grid array; and
the third terminal group and the fourth terminal group are electrically connected to the interposer by a connecting method including wire bonding.

5. The semiconductor module according to claim 4, wherein a second semiconductor chip or a second semiconductor device or a second electronic part is mounted on a second main surface side of a first semiconductor chip;
the first semiconductor chip is the semiconductor chip placed in such a way that the first main surface side is opposed to the interposer; and
the second semiconductor chip or the second semiconductor device or the second electronic part is electrically connected to the first semiconductor chip.

6. A semiconductor module comprising an interposer and the semiconductor chip as structural elements; the module comprising:
at least one semiconductor chip including the semiconductor chip, mounted on the interposer;
wherein the second main surface of the semiconductor chip is placed to be opposed to the interposer;
the third terminal group and the fourth terminal group are electrically connected to the interposer by a connecting method including a ball grid array; and
the first terminal group and the second terminal group are electrically connected to the interposer by a connecting method including wire bonding.

7. The semiconductor module according to claim 6, wherein a fourth semiconductor chip or a fourth semiconductor device or a fourth electronic part is mounted on a first main surface side of a third semiconductor chip;
the third semiconductor chip is the semiconductor chip placed in such a way that the second surface side is opposed to the interposer; and
the fourth semiconductor chip or the fourth semiconductor device or the fourth electronic part is electrically connected to the third semiconductor chip.

8. The semiconductor module according to claim 6, wherein the second main surface side of the third semiconductor chip is placed to be opposed to the interposer;
a second interposer is placed on the first main surface side of the third semiconductor chip;
the second interposer is electrically connected to the third semiconductor chip;
a fifth semiconductor chip or a fifth semiconductor device or a fifth electronic part is placed on the second interposer;
the fifth semiconductor chip or the fifth semiconductor device or the fifth electronic part is electrically connected to the second interposer; and
the second interposer is electrically connected to the interposer by a connecting method including wire bonding.
